(19) United States
(12) Patent Application Publication
(10) Pub. No.: US 2020/0266352 A1
(43) Pub. Date: Aug. 20, 2020

(54) DISPLAY DEVICE AND METHOD OF MANUFACTURING DISPLAY DEVICE

(71) Applicant: Japan Display Inc., Tokyo (JP)

(72) Inventor: Naoya KUBOTA, Tokyo (JP)

(21) Appl. No.: 16/791,247

(22) Filed: Feb. 14, 2020

(30) Foreign Application Priority Data
Feb. 20, 2019 (JP) 2019-02277

(51) Int. Cl. H01L 51/00; H01L 51/56; H01L 27/32

(52) U.S. Cl. CPC H01L 51/0022; H01L 2227/323; H01L 27/3258; H01L 51/56

(57) ABSTRACT

A method of manufacturing a display device includes forming a first inorganic insulation layer on a surface including a display region of a substrate, forming a first organic insulation layer in a first region on the first inorganic insulation layer, the first region surrounding the display region and defined as an inner region of the first inorganic insulation layer, forming a second organic insulation layer in contact with the first organic insulation layer in a second region on the first inorganic insulation layer, the second region covering the display region and surrounded by the first region, and forming a second inorganic insulation layer in contact with the first inorganic insulation layer outside the first organic insulation layer, the second inorganic insulation layer covering the first organic insulation layer and the second organic insulation layer.

### CROSS REFERENCE TO RELATED APPLICATIONS

This application is based upon and claims the benefit of priority from the prior Japanese Patent Application No. 2019-028277, filed on Feb. 20, 2019, the entire contents of which are incorporated herein by reference.

### FIELD

One embodiment of the present invention relates to a display device and a method of manufacturing a display device.

### BACKGROUND

In the display device, light emitting elements are provided in each pixel, and display the image by controlling the light emission individually. For example, in the organic EL display device using the organic EL element as the light emitting element, the organic EL element is provided in each pixel, and the organic EL element has a configuration that sandwiches a layer comprising an organic EL material (hereinafter, referred to as “organic EL layer”) between a pair of electrodes consisting of the anode electrode and the cathode electrodes. In the organic EL display device, the anode electrode is provided as an individual pixel electrode for each pixel, and the cathode electrode is provided as a common pixel electrode to which a common potential is applied across a plurality of pixel. The organic EL display device controls the light emission of the pixel by applying the voltage of the pixel electrode to the potential of the common pixel electrode for each pixel.

The organic EL layer is extremely weak in moisture, and when moisture infiltrates into the panel from the outside and reaches the organic EL layer, a non-lighting region called dark spot may be generated. Therefore, in order to prevent the penetration of moisture into the organic EL layer, measures for forming the sealing film are taken so as to cover the structure of the display region where the organic EL elements are arranged.

As the sealing film, a structure in which the organic insulating film and the inorganic insulating film covering the side surface and the upper and lower surfaces of the organic insulating film are stacked is commonly used. In order to prevent the penetration of moisture, it is necessary to arrange the organic insulating film of sufficient thickness. As a method for arranging the organic insulating film, for example, U.S. Pat. No. 9,773,994 discloses a method in which the organic insulating film is formed by a coating method.

### SUMMARY

A method of manufacturing a display device according to an embodiment of the present invention includes: forming a first inorganic insulation layer on a surface including a display region of a substrate, forming a first organic insulation layer in a first region on the first inorganic insulation layer, the first region surrounding the display region and defined as an inner region of the first inorganic insulation layer, forming a second organic insulation layer in contact with the first organic insulation layer in a second region on the first inorganic insulation layer, the second region covering the display region and surrounded by the first region, and forming a second inorganic insulation layer in contact with the first inorganic insulation layer outside the first organic insulation layer, the second inorganic insulation layer covering the first organic insulation layer and the second organic insulation layer.

A display device according to an embodiment of the present invention includes: a substrate having a display region, a first inorganic insulation layer arranged on a surface including the display region, an organic insulation layer including a first part arranged at a first region surrounding the display region and defined as an inner region of the first inorganic insulation layer, and a second part arranged at a second region covering the display region and surrounded by the first region; and a second inorganic insulation layer covering the organic insulation layer and in contact with the first inorganic insulation layer outside of the organic insulation layer. The organic insulation layer has a concave part at a boundary between the first part and the second part.

### BRIEF DESCRIPTION OF THE DRAWINGS

FIG. 1 is a top view showing a configuration of a display device according to an embodiment of the present invention;

FIG. 2 is a cross-sectional view showing a configuration of a display device according to an embodiment of the present invention;

FIG. 3 is a cross-sectional view showing a method of manufacturing a display device according to an embodiment of the present invention;

FIG. 4 is a cross-sectional view showing a method of manufacturing a display device according to an embodiment of the present invention;

FIG. 5 is a cross-sectional view showing a method of manufacturing a display device according to an embodiment of the present invention;

FIG. 6 is a cross-sectional view showing a method of manufacturing a display device according to an embodiment of the present invention;

FIG. 7 is a top view showing a method of manufacturing a display device according to an embodiment of the present invention;

FIG. 8 is a cross-sectional view showing a method of manufacturing a display device according to an embodiment of the present invention;

FIG. 9 is a cross-sectional view showing a method of manufacturing a display device according to an embodiment of the present invention;

FIG. 10 is a cross-sectional view showing a method of manufacturing a display device according to an embodiment of the present invention;

FIG. 11 is a cross-sectional view showing a method of manufacturing a display device according to an embodiment of the present invention;

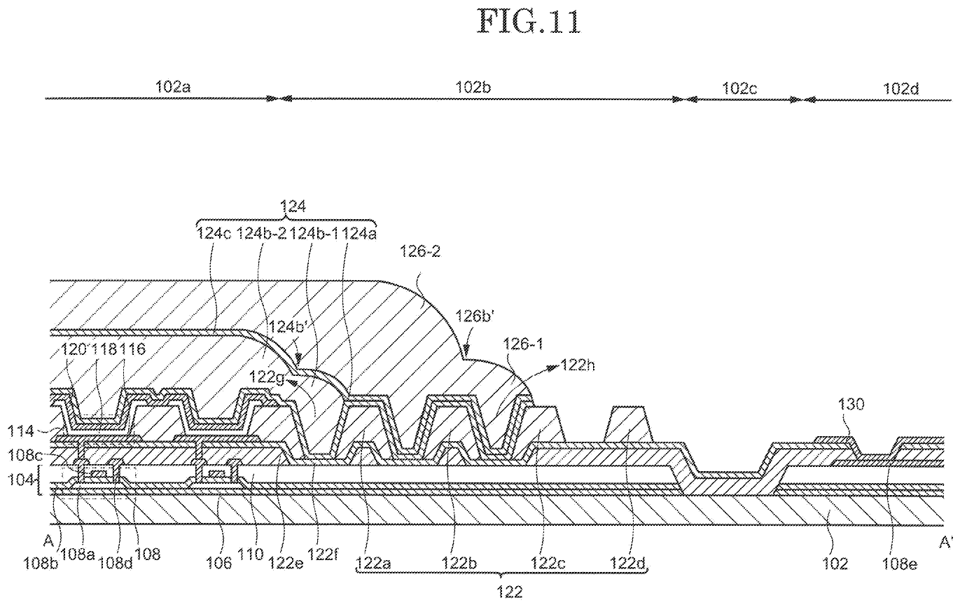

FIG. 12 is a top view showing a configuration of a display device according to an embodiment of the present invention;

FIG. 13 is a cross-sectional view showing a configuration of a display device according to an embodiment of the present invention; and

FIG. 14 is a cross-sectional view showing a configuration of a display device according to an embodiment of the present invention.

### DESCRIPTION OF EMBODIMENTS

Hereinafter, with reference to the drawings, the display device according to some embodiments of the present invention will be described in detail. However, the present invention can be implemented in many different aspects and is not intended to be construed as being limited to the description of the embodiments exemplified below. In embodiments of the present invention, the organic EL display device in particular is exemplified as a preferred application but is not limited thereto.

In order to clarify the description more clearly, as compared with the actual aspect, the width, thickness, shape, etc. of each part of the drawings may be represented schematically, but only an example, it is not intended to limit the interpretation of the present invention. Further, the dimensional ratio of the drawings may be different from the actual ratio, or a part of the configuration may be omitted from the drawings, for convenience of explanation. In this specification and the figures, elements similar to those described above concerning the above-described figures are denoted by the same reference numerals, and detailed description thereof will be omitted as appropriate.

In this specification, when a member or region is arranged “above (or below)” another member or region, unless specifically stated, such an expression includes not only the case where a member or region is arranged immediately above (or immediately below) another member or region but also the case where a member or region is arranged above (or below) another member or region with an additional component therebetween.

### First Embodiment

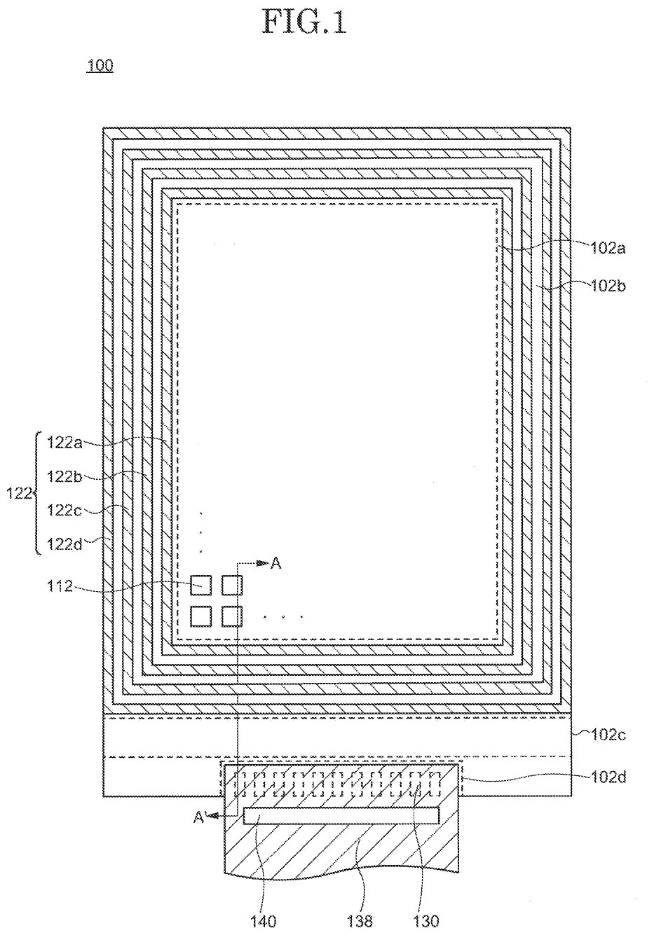

FIG. 1 is a top view showing a configuration of a display device 100 according to the present embodiment. The display device 100 includes a display region 102a, a peripheral region 102b, a bending region 102c, and a terminal region 102d.

The display region 102a is a region for displaying images. In the display region 102a, a plurality of pixel 112 is arranged. The plurality of pixel 112 is arranged in a matrix in two directions intersecting each other. In the present embodiment, the plurality of pixel 112 is arranged in a matrix in two directions orthogonal to each other. The plurality of pixel 112 is provided with a light emitting element, respectively.

The peripheral region 102b is in contact with the peripheral edge of the display region 102a and is a region surrounding the display region 102a. A driving circuit for controlling the light emission of the plurality of pixel 112 may be arranged in the peripheral region 102b. In FIG. 1, a barrier layer 122 is shown in the peripheral region 102b. The barrier layer 122, in the peripheral region 102b, includes a first barrier 122a, a second barrier 122b, a third barrier 122c, and the fourth barrier 122d. The first barrier 122a is spaced from the display region 102a and has a ring shape surrounding the display region 102a. The second barrier 122b is spaced from the first barrier 122a and has a ring shape surrounding the first barrier 122a. The third barrier 122c is spaced from the second barrier 122b and has a ring shape surrounding the second barrier 122b. The fourth barrier 122d is spaced from the third barrier 122c and has a ring shape surrounding the third barrier 122c.

The bending region 102c can be any configuration, and is a region in which the display device 100 can be bent. In the display device 100, the terminal region 102d can be arranged on the back side of the display surface of the display region 102a by bending at any straight line passing through the bending region 102c.

The terminal region 102d is a region for connecting the display device 100 and a flexible printed circuit substrate (FPC substrate) 138 or the like. The terminal region 102d is provided along one side of the display device 100, and a plurality of connecting terminals 130 is arranged.

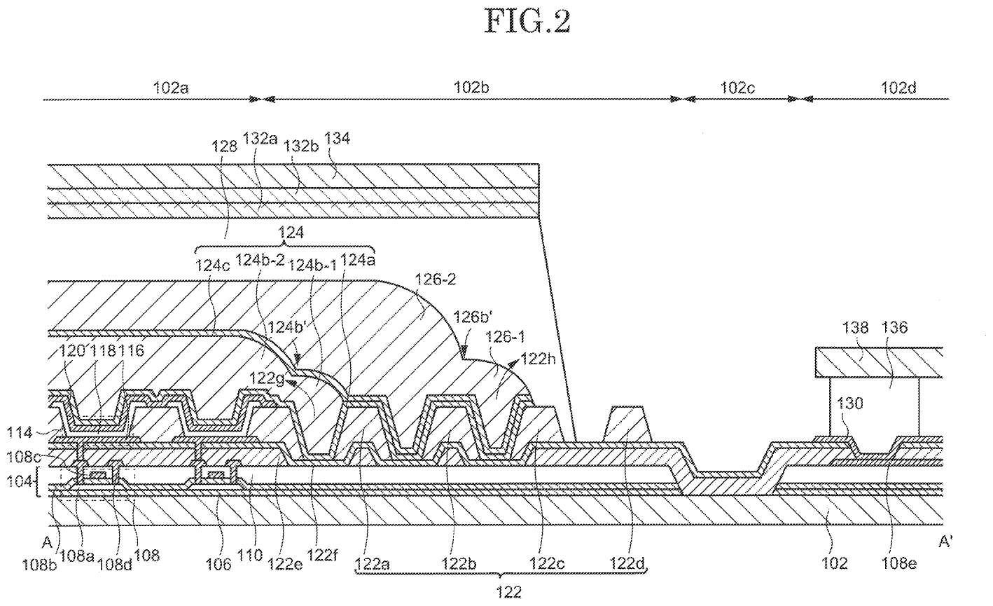

FIG. 2 is a cross-sectional view showing the configuration of the display device 100 according to the present embodiment, and shows the configuration of a cross section along the A-A′ shown in FIG. 1. The display device 100 includes a substrate 102, a circuit layer 104, the plurality of pixel 112, the barrier layer 122, a sealing layer 124, a first protective layer 126, a second protective layer 128, the plurality of connection terminals 130, a polarizing plate 132, and a cover film 134. The sealing layer 124 includes a first inorganic insulating layer 124a, an organic insulating layer 124b, and a second inorganic insulating layer 124c. The first protective layer 126 and the second protective layer 128 are arranged on the upper layer of the sealing layer 124. Further, the plurality of connection terminals 130 are arranged on the outside of the first protective layer 126.

The substrate 102 supports various elements such as circuit layers 104 and the plurality of pixel 112 arranged on one surface thereof. The materials of the substrate 102 can include glass, quartz, plastics, metals, ceramics, and the like.

When imparting flexibility to the display device 100, a base material may be formed on the substrate 102. In this case, the substrate 102 is also referred to as a support substrate. The base material is a flexible insulating layer. As a specific material of the base material, for example, a material selected from polymeric materials exemplified by polyimide, polyamide, polyester, and polycarbonate can be included.

The circuit layer 104 is arranged on one surface of the substrate 102 and includes an underlayer 106, a transistor 108, and an interlayer insulating layer 110. The circuit layer 104 is further arranged with a pixel circuit, the driving circuit or the like including the transistor 108 (not shown). The pixel circuit is arranged in each of the plurality of pixel 112 arranged in the display region 102a to control the light emission of a light emitting elements 114. The driving circuit is arranged on the peripheral region 102b to drive the pixel circuit.

The underlayer 106 can be any configuration and is arranged on the one surface of the substrate 102. The underlayer 106 is a layer for preventing impurities such as alkali metals from diffusing from the substrate 102 (and the base material) into the transistor 108 or the like. The material of the underlayer 106 may include an inorganic insulating material. The inorganic insulating material may include silicon nitride, silicon oxide, silicon nitride oxide or silicon oxynitride or the like. When the impurity concentration in the substrate 102 is low, the underlayer 106 may not be arranged, or may be formed so as to cover only a part of the substrate 102.

The transistor 108 includes a semiconductor layer 108a, a gate insulating layer 108b, a gate electrode 108c, a source drain electrode 108d, and the like. The semiconductor layer 108a is arranged in an island shape on the underlying layer 106. The material of the semiconductor layer 108a may include, for example, a group 14 element such as silicon, an oxide semiconductor or the like. The oxide semiconductor can include a group 13 element such as indium or gallium, for example, a mixed oxide of indium and gallium (IGO). When oxide semiconductor is used in the semiconductor layer 108a, the semiconductor layer 108a may further include group 12 elements, and an example is a mixed oxide containing indium, gallium, and zinc (IGZO). It is not limited to the crystallinity of the semiconductor layer 108a, and may include any crystalline state of single crystal, polycrystal, microcrystal or amorphous.

The gate insulating layer 108b is provided on the upper layer of the semiconductor layer 108a. In this embodiment, the gate insulating layer 108b is provided over a plurality of transistors 108. However, the gate insulating layer 108b may be provided at least in a region overlapping with the gate electrode 108c. As the material of the gate insulating layer 108b, a material that can be used in the underlayer 106 can be used. The gate insulating layer 108b may have a single layer structure or a stacked structure selected from these materials.

The gate electrode 108c is overlapped with the semiconductor layer 108a through the gate insulating layer 108b. In the semiconductor layer 108a, the region overlapped with the gate electrode 108c is a channel region. As the material of the gate electrode 108c, a metal such as titanium, aluminum, copper, molybdenum, tungsten, tantalum, or an alloy thereof can be used. It can be formed to have a single layer of any of these materials, or a stacked structure of a plurality of materials selected from them. For example, a structure in which a highly conductive metal such as aluminum or copper is sandwiched between the metals having a relatively high melting point such as titanium, tungsten, molybdenum or the like can be employed.

The interlayer insulating layer 110 is provided on the upper layer of the gate electrode 108c. The material of the interlayer insulating layer 110 may be a material that can be used for the underlayer 106, and it may be a single layer structure or a stacked structure selected from these materials.

The source drain electrode 108d is arranged on the interlayer insulating layer 110 and electrically connected to a source drain region of the semiconductor layer 108a through an opening arranged on the interlayer insulating layer 110 and the gate insulating layer 108b. A terminal wiring 108e is further arranged on the interlayer insulating layer 110. That is, as shown in FIG. 2, the terminal wiring 108e can be in the same layer as the source drain electrodes 108d. However, it is not limited thereto, and the terminal wiring 108e may be configured to exist in the same layer as the gate electrode 108c (not shown).

In FIG. 2, the transistor 108 illustrates a top-gate transistor, however, the structure of the transistor 108 is not limited. A bottom-gate transistor, a multi-gate transistor having a plurality of gate electrodes 108c, or a dual-gate transistor having a structure in which the top and bottom of the semiconductor layer 108a is vertically sandwiched by two gate electrodes 108c may be used. Further, in FIG. 2, although one transistor 108 is shown in each pixel 112, each pixel 112 may further include a semiconductor element such as the plurality of transistors 108 and a capacity element.

Each of the plurality of pixel 112 has the light emitting elements 114. The light emitting element 114 has a layer structure in which a first electrode 116, a light emitting layer 118 and a second electrode 120 are stacked from the substrate 102 side. Carriers are injected from the first electrode 116 and the second electrode 120 into the light emitting layer 118, and recombination of carriers occurs in the light emitting layer 118. The light emitting molecule in the light emitting layer 118 becomes an excited state, and the light emission is obtained through the process of relaxing this to the ground state.

The first electrode 116 is arranged on the upper layer than the planarized insulating layer 122e. The first electrode 116 also covers an opening provided in the planarized insulating layer 122e and an inorganic insulating layer 122f, and is provided so as to be electrically connected to the source drain electrode 108d. Thus, a current is supplied to the light emitting element 114 through the transistor 108. When light emission from the light emitting element 114 is extracted from the second electrode 120 side, the material of the first electrode 116 is selected from a material capable of reflecting visible light. In this case, the first electrode 116 is made of a high reflectivity metal or an alloy thereof, such as silver or aluminum. Alternatively, a layer of conductive oxide having a light transmittance property is formed on the layer containing these metals or alloys. Examples of the conductive oxides include ITO and IZO. Conversely, when the light emission from the light emitting element 114 is extracted from the first electrode 116 side, ITO or IZO may be used for the material of the first electrode 116.

The light emitting layer 118 is provided so as to cover the first electrode 116. Configuration of the light emitting layer 118 can be appropriately selected, for example, can be configured by combining a carrier injection layer, a carrier transport layer, the light emitting layer 118, a carrier blocking layer, and an exciton blocking layer or the like. The light emitting layer 118 can be configured to include different materials for each pixel 112. By appropriately selecting the materials used for the light emitting layers 118, different light emitting colors can be obtained from each pixel 112. Alternatively, the structures of the light emitting layers 118 may be identical between the pluralities of pixel 112. In such a configuration, since the same emitting color is output from the light emitting layer 118 of each pixel 112, for example, the light emitting layer 118 may be configured to emit white light, and various colors (e.g., red, green, blue) may be extracted from the pixel 112 using a color filter, respectively.

The second electrode 120 is provided on the upper layer of the light emitting layer 118. The second electrode 120 may be provided in common with the plurality of pixel 112, as in the present embodiment. In a plan view, the region where the first electrode 116 and the light emitting layer 118 is in contact is a light emitting region. When the light emission from the light emitting element 114 is extracted from the second electrode 120 side, the material of the second electrode 120 is selected from a conductive oxide or the like having a light transmitting property such as ITO. Alternatively, the metal described above can be formed with a thickness that allows visible light to transmit. In this case, conductive oxide having a light transmitting property may be further stacked.

The barrier layer 122 is provided on one surface of the substrate 102. The barrier layer 122 has the first barrier 122a, the second barrier 122b, the third barrier 122c, the fourth barrier 122d, a planarized insulating layer 122e and the inorganic insulating layer 122f.

The first barrier 122a is spaced from the display region 102a in a plan view, and has a ring shape surrounding the display region 102a.

Thus, the ring shape of the groove part 122g is formed between the display region 102a and the first barrier 122a. Although the detail will be described later, when forming the organic insulating layer 124b constituting the sealing layer 124 in the manufacturing process, the organic insulating layer 124b must be selectively formed in regions within the surface of the substrate 102 so that it covers the display region 102a and does not expand to the end of the substrate 102. If the organic insulating layer 124b extends to the end of the substrate 102, there is a concern that moisture may enter the display device 100 from the end through the organic insulating layer 124b. The organic insulating layer 124b is selectively applied to the display region 102a in two steps using, for example, an ink jet method. At this time, the first barrier 122a has a function of blocking the organic insulating layer 124b from spreading outside.

Therefore, the first barrier 122a is arranged so that the distance from the display region 102a is 10 μm or more 1000 μm or less, preferably 10 μm or more 200 μm or less. Here, the end portion of the display region 102a assumed to be the end portion of the light emitting layer 118. If the distance between the display region 102a and the first barrier 122a is smaller than this range, sufficient function for blocking the organic insulating layer 124b cannot be obtained when forming the organic insulating layer 124b. When the distance between the display region 102a and the first barrier 122a is larger than this range, narrowing of the display device 100 becomes difficult. The first barrier 122a is preferably 5 μm or more 200 μm or less in width. If the width of the first barrier 122a is smaller than this range, it becomes difficult to form a first barrier of sufficient height in the manufacturing process. If the width of the first barrier 122a is larger than this range, narrowing of the picture frame of the display device 100 becomes difficult. The maximum height of first barrier 122a is preferably 1 μm or 5 μm or less. If the height of the first barrier 122a is smaller than this range, sufficient function for blocking the organic insulating layer 124b cannot be obtained when applying the organic insulating layer 124b, . When the height of the first barrier 122a is larger than this range, it becomes difficult to form the barrier layer 122.

The second barrier 122b is spaced from the first barrier 122a in a plan view, and has a ring shape surrounding the first barrier 122a. The second barrier 122b is a spare wall when the organic insulating layer 124b has flowed out to the outside of the first barrier 122a. Therefore, the second barrier 122b is preferably arranged in the same configuration as the first barrier 122a.

The third barrier 122c is spaced from the second barrier 122b in a plan view, and has a ring shape surrounding the second barrier 122b. Thus, the ring shape of the groove part 122h is formed between the third barrier 122c and the second barrier 122b. Although the details will be described later, when the sealing layer 124 covering the plurality of connection terminals 130 is patterned to expose the plurality of connection terminals 130, the sealing layer 124 is etched using the first protective layer 126 as a mask in the manufacturing process. During this etching, the end of the first protective layer 126 recedes. If the end of the first protective layer 126 is too receded, the etching of the sealing layer 124 is performed to the region where the three layers of the first inorganic insulating layer 124a, the organic insulating layer 124b and the second inorganic insulating layer 124c are stacked. Therefore, there is a concern that the organic insulating layer 124b is exposed. When the organic insulating layer 124b is exposed, moisture enters therefrom, and then passes through the first inorganic insulating layer 124a, so that the light emitting layer 118 is deteriorated. As a result, the yield and reliability of the display device 100 decrease. Since the first inorganic insulating layer 124a is provided on the barrier layer 122 having concavity and convexity , cracks or the like is likely to occur, which can be an intrusion path of moisture.

Therefore, the second barrier 122b and the third barrier 122c are arranged, and forming the first protective layer 126 so that the end portion of the first protective layer 126 is arranged on the third barrier 122c. Accordingly, the film thickness of the first protective layer 126 in the peripheral region 102b can be increased by the groove part between the first barrier 122a and the second barrier 122b, and the groove part 122h between the second barrier 122b and the third barrier 122c. This prevents the end of the first protective layer 126 from receding during etching of the sealing layer 124. This prevents the sealing layers 124 to be etched to unintentional regions, and prevents the organic insulating layer 124b from being exposed.

Further, in the step described later, the first inorganic insulating layer 124a and the second inorganic insulating layer 124c are removed using the first protective layer 126 as a mask.

At this time, if the first protective layer 126 inadvertently flows out to the vicinity of the end of the substrate, the region where the first inorganic insulating layer 124a and the second inorganic insulating layer 124c is not removed is enlarged. In particular, when the frame becomes narrower and the distance between the display region 102a and the terminal region 102d is reduced, the exposure of the connection terminal 130 may become difficult. The effect of blocking the first protective layer 126 can be expected by the third barrier 122c, and the groove part 122h.

Therefore, the distance between the third barrier 122c and the second barrier 122b is 10 μm or more 1000 μm or less, preferably 10 μm or more 200 μm or less. When the distance between the third barrier 122c and the second barrier 122b is smaller than this range, a region having a sufficient thickness in the vicinity of the end of the first protective layer 126 cannot be sufficiently secured, and the function of preventing recession of the end portion of the first protective layer 126 is not sufficiently obtained. When the distance between the third barrier 122c and the second barrier 122b is larger than this range, narrowing of the display device 100 become difficult. Further, the maximum height of the third barrier 122c is preferably 1 μm or 5 μm or less. When the height of the third barrier 122c is smaller than this range, the film thickness in the vicinity of the end portion of the first protective layer 126 cannot be made sufficiently large, and the function of preventing recession of the end portion of the first protective layer 126 cannot be sufficiently obtained. If the height of the third barrier 122c is larger than this range, it becomes difficult to form the barrier layer 122.

The fourth barrier 122d is spaced from the third barrier 122c in a plan view, and has a ring shape surrounding the third barrier 122c. The fourth barrier 122d is a spare wall when the first protective layer 126 has flowed out to the outside of the third barrier 122c. Therefore, the fourth barrier 122d is preferably arranged in the same configuration as the third barrier 122c.

The configurations of the first barrier 122a, the second barrier 122b, the third barrier 122c, and the fourth barrier 122d in the barrier layer 122 have been described above. They are separated from each other in a plan view. As the material of the first barrier 122a, the second barrier 122b, the third barrier 122c, and the fourth barrier 122d, it is possible to use an organic insulating material such as an epoxy resin, acrylic resin.

The planarized insulating layer 122e is arranged on the upper layer of the circuit layer 104 and on the lower layer of the light emitting element 114. The planarized insulating layer 122e provides a flat surface by absorbing concavity and convexity due to semiconductor elements such as the transistors 108. As the material of the planarized insulating layer 122e, a material which can be used for the first barrier 122a, the second barrier 122b, the third barrier 122c, and the fourth barrier 122d can be used.

The inorganic insulating layer 122f can be any configuration and has a function of protecting a semiconductor element such as the transistor 108. Furthermore, a capacitor can be formed between the first electrode 116 of the light emitting element 114 and the electrode (not shown) formed under the inorganic insulating layer 122f so as to sandwich the inorganic insulating layer 122f with the first electrode 116.

A plurality of openings is arranged in the planarized insulating layer 122e and the inorganic insulating layer 122f. One of which is provided for electrically connecting the first electrode 116 of the light emitting element 114 and the source drain electrode 108d of the transistor 108. The other is provided to expose a part of the terminal wiring 108e. The terminal wiring 108e exposed by the opening is electrically connected to the FPC substrate 138, for example, by an anisotropic conductive film 136 or the like.

The sealing layer 124 is provided on the upper layer of the plurality of pixel 112 and the barrier layer 122. The sealing layer 124 includes the first inorganic insulating layer 124a, the organic insulating layer 124b and the second inorganic insulating layer 124c.

The first inorganic insulating layer 124a covers the concave-convex surfaces caused by the plurality of pixel 112 and the barrier layer 122. The outer end of the first inorganic insulating layer 124a is arranged at the outside of the second barrier 122b and on the third barrier 122c or at the position overlapping with the groove part 122h. That is, the first inorganic insulating layer 124a covers the bottom surface and the side walls of the groove part 122g between the plurality of pixel 112 and the first barrier 122a. Further, the first inorganic insulating layer 124a covers the bottom and side walls of the groove part between the first barrier 122a and the second barrier 122b, and the bottom and side walls of the groove part 122h between the second barrier 122b and the third barrier 122c.

The first inorganic insulating layer 124a has at least the following two roles. One is that the first inorganic insulating layer 124a is arranged so that the organic insulating layer 124b, which is arranged on the upper layer of the first inorganic insulating layer 124a and through which moisture easily permeates, does not contact the light emitting element 114. Thus, it is possible to prevent the moisture contained in the organic insulating layer 124b or the moisture entering the organic insulating layer 124b from the outside of the display device 100 from reaching the light emitting layer 118 and deteriorating the light emitting layer 118. The other is that the first inorganic insulating layer 124a is provided in order to prevent the first barrier 122a and the second barrier 122b from causing an entry path of moisture through organic materials. Thus, it is possible to prevent the moisture contained in the third barrier 122c or the moisture entering the third barrier 122c from the outside of the display device 100 from reaching the inside of the display region 102a and deteriorating the light emitting layer 118.

Therefore, as the material of the first inorganic insulating layer 124a, an insulating material having low moisture permeability is preferable. As a specific material of the first inorganic insulating layer 124a, for example, silicon oxide, silicon nitride, silicon oxynitride, aluminum oxide, aluminum nitride, aluminum oxynitride, or the like can be used. Further, a structure in which pluralities of materials selected from these are stacked may be used.

The organic insulating layer 124b has a first part of an organic insulation layer 124b-1 and a second part of an organic insulation layer 124b-2. The first part of the organic insulation layer 124b-1 and the second part of the organic insulation layer 124b-2 of the organic insulating layer 124b are provided on the upper layer of the first inorganic insulating layer 124a. The first part of the organic insulation layer 124b-1 is a ring shape surrounding the display region 102a. The first part of the organic insulation layer 124b-1 is arranged in a first region of the peripheral region 102b defined as a region inside the first inorganic insulating layer 124a. The outer end of the first part of the organic insulation layer 124b-1 is arranged on the first barrier 122a. However, it is not limited to this, and the outer end of the first part of the organic insulation layer 124b-1 may be arranged between the display region 102a and the first barrier 122a or between the first barrier 122a and the second barrier 122b. The first part of the organic insulation layer 124b-1 has a rounded convex shape with no corners from the outer end toward the display region 102a when viewed in cross-section.

However, it is not limited to this, the surface shape of the first part of the organic insulation layer 124b-1 may have less concave-convex structure.

Distance between the uppermost part of the first part of the organic insulation layer 124b-1 and the upper surface of the first inorganic insulating layer 124a on the first barrier 122a is preferably in the range of 2 μm or more and 15 μm or less. Here, the uppermost part of the first part of the organic insulation layer 124b-1 may be a boundary between the first part of the organic insulation layer 124b-1 and the second part of the organic insulation layer 124b-2. That is, the uppermost part of the first part of the organic insulation layer 124b-1 of the organic insulating layer 124b has larger distance from the substrate 102 than the upper surface of the first inorganic insulating layer 124a on the first barrier 122a. If the height of the first part of the organic insulation layer 124b-1 is less than this range, it does not provide enough function to block the second part of the organic insulation layer 124b-2 when applied it. The width of the first part of the organic insulation layer 124b-1 is preferably in the range of 10 μm or more and 100 μm or less. If the width of the first part of the organic insulation layer 124b-1 is smaller than this range, it becomes difficult to form the first part of the organic insulation layer 124b-1 of enough high. With such a configuration, the first part of the organic insulation layer 124b-1 of the organic insulating layer 124b can block so that the second part of the organic insulation layer 124b-2 of the organic insulating layer 124b does not expand to its outside.

The second part of the organic insulation layer 124b-2 is arranged to cover the display region 102a. The second part of the organic insulation layer 124b-2 is arranged in a second region including the display region 102a and the peripheral region 102b surrounded by the first region. The outer end of the second part of the organic insulation layer 124b-2 is in contact with the first part of the organic insulation layer 124b-1. The second part of the organic insulation layer 124b-2 has a rounded convex shape with no corners from the outer end toward the display region 102a when viewed in cross-section. The second part of the organic insulation layer 124b-2 is substantially flat in the display region 102a. However, it is not limited to this, the second part of the organic insulation layer 124b-2 may have less concave-convex structures in the display region 102a. The organic insulating layer 124b is provided to planarize the concavity and convexity of the display region 102a due to the plurality of pixel 112.

If the second inorganic insulating layer 124c is provided on the organic insulating layer 124b without sufficient planarization of the concavity and convexity of the plurality of pixel 112, the second inorganic insulating layer 124c can not completely coat the concavity and convexity remaining on the organic insulating layer 124b. In some cases, defects such as cracks may occur in the second inorganic insulating layer 124c, which may cause a moisture entry path.

Distance between the uppermost part of the second part of the organic insulation layer 124b-2 and the uppermost part of the first part of the organic insulation layer 124b-1 is preferably in the range of 5 μm or 20 μm or less. That is, the distance from the substrate 102 is greater at the uppermost part of the second part of the organic insulation layer 124b-2 than at the uppermost part of the first part of the organic insulation layer 124b-1. Furthermore, the contact angle between the second part of the organic insulation layer 124b-2 and the first part of the organic insulation layer 124b-1 is larger than the contact angle between the first part of the organic insulation layer 124b-1 and the first inorganic insulating layer 124a. That is, the inclination of the convex shape of the second part of the organic insulation layer 124b-2 is steeper than the inclination of the convex shape of the first part of the organic insulation layer 124b-1. In display region 102a, the distance between the top of the first inorganic insulating layer 124a and the top of the second part of the organic insulation layer 124b-2 is preferably in the range of 2 μm or more and 30 μm or less. With such a configuration, the organic insulating layer 124b can be form sufficiently thick in the display region 102a, and it is possible to suppress unevenness or the like caused by without sufficient planarization of the concavity and convexity and foreign matter entering the display region 102a.

The boundary between the first part of the organic insulation layer 124b-1 and the second part of the organic insulation layer 124b-2 has a concave 124b′. The concave 124b′ which is the end of the second part of the organic insulation layer 124b-2 has a wavy shape at the periphery of the display region 102a when viewed from the top. That is, the end of the second part of the organic insulation layer 124b-2 has a plurality of concave-convex shapes in the outer direction of the display region 102a at the peripheral region 102b. On the other hand, the end of the first part of the organic insulation layer 124b-1 may have less concave-convex structures. Since the boundary between the first part of the organic insulation layer 124b-1 and the second part of the organic insulation layer 124b-2 has such a configuration, the adhesion between the organic insulating layer 124b and the second inorganic insulating layer 124c which is the upper layer of the organic insulating layer 124b can be improved.

The second inorganic insulating layer 124c is provided on the upper layer of the organic insulating layer 124b. The end of the second inorganic insulating layer 124c is also arranged at the outside of the second barrier 122b and on the third barrier 122c or at the position overlapping with the groove part 122h. In this embodiment, the second inorganic insulating layer 124c is arranged along the end of the first inorganic insulating layer 124a. Since the end of the first inorganic insulating layer 124a and the second inorganic insulating layer 124c are arranged on the third barrier 122c, the second barrier 122b can be completely coat by the first inorganic insulating layer 124a and the second inorganic insulating layer 124c. Thus, the effect of preventing moisture from entering to the display region 102a can be enhanced. The organic insulating layer 124b is sealed by the first inorganic insulating layer 124a and the second inorganic insulating layer 124c. With such a configuration, it is possible to block the penetration path of moisture from the outside to the inside of the display device 100 through the organic insulating layer 124b. As the material of the second inorganic insulating layer 124c, an insulating material having low moisture permeability is preferable to use, and a material similar to that of the first inorganic insulating layer 124a can be used.

The second inorganic insulating layer 124c does not necessarily have to have its end arranged along the end of the first inorganic insulating layer 124a. The sealing layer 124 may be configured such that the organic insulating layer 124b is sealed by the first inorganic insulating layer 124a and the second inorganic insulating layer 124c.

The first protective layer 126 has a first part of a first protective layer 126-1 and a second part of a first protective layer 126-2. The first part of the first protective layer 126-1 and a second part of a first protective layer 126-2 of the first protective layer 126 are provided on the upper layer of the sealing layer 124, that is, on the upper layer of the second inorganic insulating layer 124c. The first part of the first protective layer 126-1 is the ring shape surrounding the first region and second regions where the organic insulating layer 124b is arranged. The first part of the first protective layer 126-1 is arranged in a third region of the peripheral region 102b defined as a region inside the first inorganic insulating layer 124a. The outer end of the first part of the first protective layer 126-1 is arranged at the outside of the second barrier 122b and on the third barrier 122c or at the position overlapping with the groove part 122h. The first part of the first protective layer 126-1 has a rounded convex shape with no corners from the outer end toward the display region 102a when viewed in cross-section. However, it is not limited to this, the surface shape of the first part of the first protective layer 126-1 may have less concave-convex structure.

Distance between the uppermost part of the first part of the first protective layer 126-1 and the upper surface of the second inorganic insulating layer 124c on the third barrier 122c is preferably in the range of 2 μm or more and 15 μm or less. Here, the uppermost part of the first part of the first protective layer 126-1 may be a boundary between the first part of the first protective layer 126-1 and the second part of the first protective layer 126-2. That is, the uppermost part of the first part of the first protective layer 126-1 of the first protective layer 126 has larger distances from the substrate 102 than the upper surface of the second inorganic insulating layer 124c on the third barrier 122c. If the height of first part of the first protective layer 126-1 is less than this range, it does not provide enough function to block the second part of the first protective layer 126-2 when apply it. The width of the first part of the first protective layer 126-1 is preferably in the range of 10 μm or more and 100 μm or less. If the width of the first part of the first protective layer 126-1 is less than this range, it becomes difficult to form the first part of the first protective layer 126-1 of enough height. With such a configuration, the first part of the first protective layer 126-1 of the first protective layer 126 can block so that the second part of the first protective layer 126-2 of the first protective layer 126 does not spread on the outer side thereof.

The second part of the first protective layer 126-2 is arranged to cover the display region 102a. The second part of the first protective layer 126-2 is arranged in a fourth region including the display region 102a and the peripheral region 102b surrounded by the third region. The outer end of the second part of the first protective layer 126-2 is in contact with the first part of the first protective layer 126-1. The second part of the first protective layer 126-2 has a rounded convex shape with no corners from the outer end toward the display region 102a when viewed in cross-section. The second part of the first protective layer 126-2 is substantially flat in the display region 102a. However, it is not limited to this, the second part of the first protective layer 126-2 may have less concave-convex structures in the display region 102a.

In this embodiment, the first protective layer 126 is arranged along the end of the second inorganic insulating layer 124c. The first protective layer 126 also fills the groove part between the first barrier 122a and the second barrier 122b, and the groove part 122h between the second barrier 122b and the third barrier 122c. Thus, the thickness of the first protective layer 126 in the peripheral region 102b is thicker than the thickness of the first protective layer 126 in the display region 102a. As the material of the first protective layer 126, a material similar to the material that can be used for the aforementioned organic insulating layer 124b can be used.

Distance between the uppermost part of the second part of the first protective layer 126-2 and the uppermost part of the first part of the first protective layer 126-1 is preferably in the range of 5 μm or more and 20 μm or less. That is, the distance from the substrate 102 is greater at the uppermost part of the second part of the first protective layer 126-2 than at the uppermost part of the first part of the first protective layer 126-1. In addition, the contact angle between the second part of the first protective layer 126-2 and the first part of the first protective layer 126-1 is larger than the contact angle between the first part of the first protective layer 126-1 and the second inorganic insulating layer 124c. That is, the inclination of the convex shape of the second part of the first protective layer 126-2 is steeper than the inclination of the convex shape of the first part of the first protective layer 126-1. With such a configuration, the first protective layer 126 can be formed sufficiently thick, and the concavity and convexity at the upper surface of the first protective layer 126 can be formed smaller than the concavity and convexity in the barrier layer 122.

The boundary between the first part of the first protective layer 126-1 and the second part of the first protective layer 126-2 has a concave 126b′. The concave 126b′ which is the end of the second part of the first protective layer 126-2 has a wavy shape at the periphery of the display region 102a when viewed from the top. That is, the end of the second part of the first protective layer 126-2 has the plurality of concave-convex shapes in the outer direction of the display region 102a at the peripheral region 102b. On the other hand, the end of the first part of the first protective layer 126-1 may have less concave-convex structures. Since the boundary between the first part of the first protective layer 126-1 and the second part of the first protective layer 126-2 has such a configuration, the adhesion between the first protective layer 126 and the second protective layer 128 which is the upper layer of the first protective layer 126 can be improved.

The second protective layer 128 can be any configuration and physically protects the display device 100. Materials of the second protective layer 128 may include polymeric materials such as esters, epoxy resins, acrylic resins, and the like. The second protective layer 128 can be formed by applying a printing method, a laminating method, or the like.

The plurality of connection terminals 130 is arranged on the one surface of the substrate 102. Each of the plurality of connection terminals 130 is electrically connected to the connecting wiring through an opening arranged in the inorganic insulating layer 122f and the planarized insulating layer 122e. The plurality of connection terminals 130 is arranged outside of the first protective layer 126 in a plan view.

The polarizing plate 132 may have, for example, a stacked structure of a λ/4 plate 132a and a linear polarizing plate 132b arranged thereon. After the light incident from the outside of the display device 100 becomes linearly polarized light by passing through the linearly polarized plate 132b, it becomes a circularly polarized light in the clockwise direction by passing through the λ/4 plate 132a. The circularly polarized light becomes circularly polarized light in the counterclockwise direction when reflected by the first electrode 116, and it becomes linearly polarized light by passing through again λ/4 plate 132a. The plane of polarization of the linearly polarized light at this time is orthogonal to the linearly polarized light before reflection. Therefore, the light cannot pass through the linearly polarized plate 132b. As a result, reflection of the outside light is suppressed by installing the polarizing plate 132, and a high-contrast image can be provided.

The cover film 134 can be any configuration in the present embodiment, and is provided on the upper layer of the polarizing plate 132. The cover film 134 physically protects a polarizer 132.

According to the configuration of the display device 100, it is possible to prevent deterioration of the sealing layer 124.

Thus, it is possible to provide the display device 100 with improved production yield and reliability.

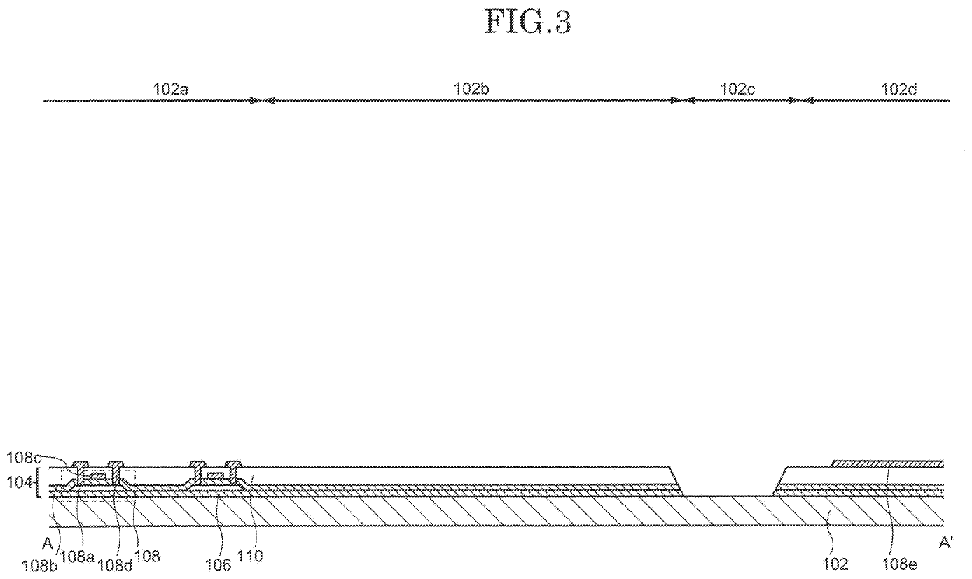

It will now be described in detail about a method of manufacturing the display device 100 according to the present embodiment. FIGS. 3 to 10 are cross-sectional views showing a method of manufacturing the display device 100 according to the present embodiment. The substrate 102 supports various elements such as the circuit layers 104 and the plurality of pixel 112 arranged over one surface thereof. Accordingly, the substrate 102 may be made of materials having heat resistance to the temperatures of the processes of the various elements formed thereon and chemical stability to the chemicals used in the processes. The materials of the substrate 102 can include glass, quartz, plastics, metals, ceramics, and the like.

In order to impart flexibility to the display device 100, a base material may be formed on the substrate 102. In this case, the substrate 102 is also referred to as a support substrate. The base material is a flexible insulating layer. As a specific materials of the base material may include materials selected from polymeric materials exemplified, for example, polyimide, polyamide, polyester, and polycarbonate. The base material can be formed by applying, for example, a printing method, an ink jet method, a spin coating method, a wet film formation method such as a dip coating method, or a laminating method.

Next, a method for forming the circuit layer 104 on one surface of the substrate 102 will be described with reference to FIG. 3. First, the underlayer 106 is formed. The material of the underlayer 106 may include the inorganic insulating material.

The inorganic insulating material may include silicon nitride, silicon oxide, silicon nitride oxide or silicon oxynitride or the like. The underlayer 106 can be formed so as to have a single layer, or a stacked structure by applying a chemical vapor deposition method (CVD method) or a sputtering method or the like. The underlayer 106 can be any configuration, and does not necessarily need to be provided.

Next, the semiconductor layer 108a is formed. The semiconductor layer 108a may include a group 14 element such as silicon described above, or an oxide semiconductor. When the semiconductor layer 108a includes silicon, the semiconductor layer 108a may be formed by a CVD method using a silane gas or the like as a raw material. Crystallization may be performed by heat treatment or irradiating light such as a laser with respect to amorphous silicon obtained by this. When the semiconductor layer 108a includes an oxide semiconductor, the semiconductor layer 108a can be formed by utilizing a sputtering method or the like.

Next, the gate insulating layer 108b is formed so as to cover the semiconductor layer 108a. The gate insulating layer 108b can be formed so as to have a single layer structure or a stacked structure, and can be formed by the method similar to that of the underlayer 106.

Next, the gate electrode 108c is formed on the gate insulating layer 108b. The material of the gate electrode 108c may include metals such as titanium, aluminum, copper, molybdenum, tungsten, tantalum or an alloy thereof. A single layer of any of these materials or a stacked structure of a plurality of materials selected from these can be formed. For example, a structure in which a highly conductive metal such as aluminum or copper is sandwiched between the metals having a relatively high melting point such as titanium, tungsten, molybdenum or the like can be employed. The gate electrode 108c can be formed using a sputtering method or a CVD method.

The interlayer insulating layer 110 is formed on the gate electrode 108c. The interlayer insulating layer 110 is arranged on the upper layer of the gate electrode 108c. As the material of the interlayer insulating layer 110, a material that can be used for the underlayer 106 can be used, and it may have a single layer structure or a stacked structure selected from these materials. The interlayer insulating layer 110 can be formed by the method similar to that of the underlayer 106. When the interlayer insulating layer 110 has a stacked structure, for example, a layer including an organic material may be formed, and then a layer containing an inorganic material may be stacked.

Next, etching is performed on the interlayer insulating layer 110 and the gate insulating layer 108b to form an opening that reaches the semiconductor layer 108a. The opening can be formed, for example, by performing plasma etching in a gas containing fluorine-containing hydrocarbons. Further, in the same step, the underlayer 106, the gate insulating layer 108b and the interlayer insulating layer 110 of the circuit layer 104 in the bending region 102c are removed. The inorganic insulating material is likely to cause defects such as cracks by bending, and there is concern that the penetration path of moisture may be generated from it. Therefore, it is preferable to remove the inorganic insulating materials in the bending region 102c.

The metal layer is then formed over the opening and etched to form the source drain electrode 108d. In this embodiment, the terminal wiring 108e is formed at the same time as the source drain electrode 108d is formed. Therefore, the source drain electrode 108d and the terminal wiring 108e can be present in the same layers. The metal layer can have a structure similar to that of the gate electrode 108c and can be formed using a method similar to the formation of the gate electrode 108c.

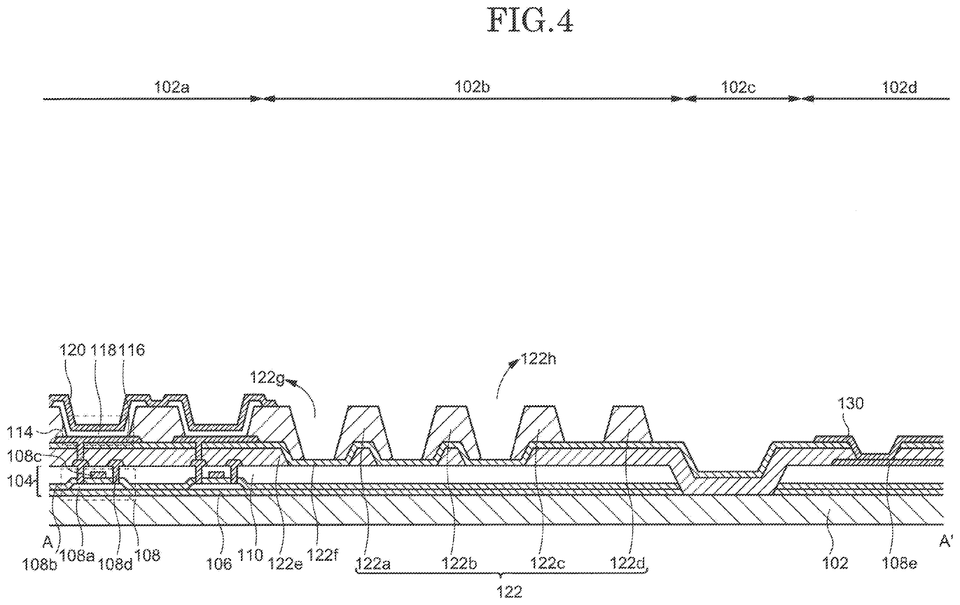

Next, a method for forming the plurality of pixel 112, the barrier layer 122, and the plurality of connection terminals 130 on one surface of the substrate 102 will be described with reference to FIG. 4. Each of the plurality of pixel 112 has the light emitting elements 114. The barrier layer 122 has the first barrier 122a, the second barrier 122b, the third barrier 122c, the fourth barrier 122d, planarized insulating layer 122e, and the inorganic insulating layer 122f. The first barrier 122a surrounds the display region 102a, the second barrier 122b surrounds the first barrier 122a, the third barrier 122c surrounds the second barrier 122b, and the fourth barrier 122d surrounds the third barrier 122c. The connection terminal 130 is arranged outside of the fourth barrier 122d.

Next, the planarized insulating layer 122e is formed. The planarized insulating layer 122e is formed so as to cover the source-drain electrode 108d and the terminal wiring 108e. The planarized insulating layer 122e has a function of absorbing concavity and convexity and inclination due to the transistor 108, the terminal wiring 108e or the like, and providing a flat surface. As the material of the planarized insulating layer 122e, the organic insulating material can be used. The organic insulating materials include polymeric materials such as epoxy resin, acrylic resin, polyimide, polyamide, polyester, polycarbonate, and polysiloxane. The film can be formed by a wet film formation method or the like.

Next, the inorganic insulating layer 122f is formed on the planarized insulating layer 122e. As described above, the inorganic insulating layer 122f is not only functions as a protective layer to the transistor 108 but also forms a capacitance with the first electrode 116 of the light emitting element 114 formed later. Therefore, it is preferable to use a material having a relatively high dielectric constant. For example, silicon nitride, silicon nitride oxide, silicon oxynitride or the like can be used. As the film formation method, a CVD method or a sputtering method can be applied.

Next, the inorganic insulating layer 122f and the planarized insulating layer 122e are etched to form openings using the source-drain electrode 108d and the terminal wiring 108e as an etching stopper. Thereafter, the first electrode 116 and the connection terminal 130 are formed so as to cover these openings.

When the light emission from the light emitting element 114 is extracted from the second electrode 120 side, the first electrode 116 is configured to reflect visible light. In this case, a high reflectivity metal or an alloy thereof such as silver or aluminum is used for the first electrode 116. Alternatively, a layer of conductive oxide having a light transmittance property is formed on a layer containing these metals or alloys. Examples of the conductive oxides include ITO and IZO. In the case of taking out the light emission from the light emitting element 114 from the first electrode 116 side, the first electrode 116 may be formed using ITO or IZO.

In the present embodiment, the first electrode 116 and the connecting electrode are formed on the inorganic insulating layer 122f. Therefore, for example, the metal layer can be formed so as to cover the opening, a layer comprising a conductive oxide that transmits visible light can be formed, and the first electrode 116 and the connecting electrode can be formed by processing by etching.

Next, the first barrier 122a, the second barrier 122b, the third barrier 122c, and the fourth barrier 122d are formed.

When forming the organic insulating layer 124b that constitutes the sealing layer 124 in a subsequent manufacturing process, the organic insulating layer 124b needs to be selectively formed in regions within the surface of the substrate 102 so that it covers the display region 102a and does not expand to the end of the substrate 102. The organic insulating layer 124b is selectively formed in the display region 102a in two steps, for example, using an ink jet method. At this time, the first barrier 122a has a function of blocking the organic insulating layer 124b from spreading to the outside.

Further, when exposing the plurality of connection terminals 130 by patterning the sealing layer 124 in the later manufacturing process, the sealing layer 124 is etched using the first protective layer 126 as a mask. During this etching, the end of the first protective layer 126 may recede. If the end of the first protective layer 126 is too receded, it is concerned that the organic insulating layer 124b is exposed by the etching of the sealing layer 124 up to the region where the three layers of the first inorganic insulating layer 124a, the organic insulating layer 124b and the second inorganic insulating layer 124c are stacked. When the organic insulating layer 124b is exposed, it becomes an intrusion path of moisture, and the moisture entered to the organic insulating layer 124b passes through the first inorganic insulating layer 124a, so that the light emitting layer 118 is deteriorated. As a result, the yield and reliability of the display device 100 deteriorate. Since the first inorganic insulating layer 124a is provided on the barrier layer 122 having concavity and convexity, cracks or the like are likely to occur, which can be an intrusion path of moisture.

In order to prevent the recession of the end portion of the first protective layer 126, at least the film thickness near the end portion of the first protective layer 126 may be increased. The third barrier 122c is provided for that purpose, and the groove part 122h between the third barrier 122c and the second barrier 122b is filled with the first protective layer 126, so that the film thickness in the vicinity of the end of the first protective layer 126 is increased.

As the material of the first barrier 122a, the second barrier 122b, the third barrier 122c, and the fourth barrier 122d, a material which can be used for the planarized insulating layer 122e, such as epoxy resin or acrylic resin, can be used, and it can be formed by a wet film formation method.

The light emitting layer 118 and the second electrode 120 are formed to cover the first electrode 116 and the barrier layer 122. The light emitting layer 118 mainly include an organic compound, and it can be formed by applying the wet film formation method such as an ink jet method or a spin coating method, or a dry film formation method such as vapor deposition.

When the light emission from the light emitting element 114 is extracted from the first electrode 116 side, a metal such as aluminum, magnesium, and silver or these alloys may be used as the material of the second electrode 120. When the light emission from the light emitting element 114 is extracted from the second electrode 120, a conductive oxide having a light transmitting property such as ITO may be used as a material of the second electrode 120. Alternatively, the metal described above can be formed with a thickness that allows visible light to transmit. In this case, conductive oxide having a light transmitting property may be further stacked.

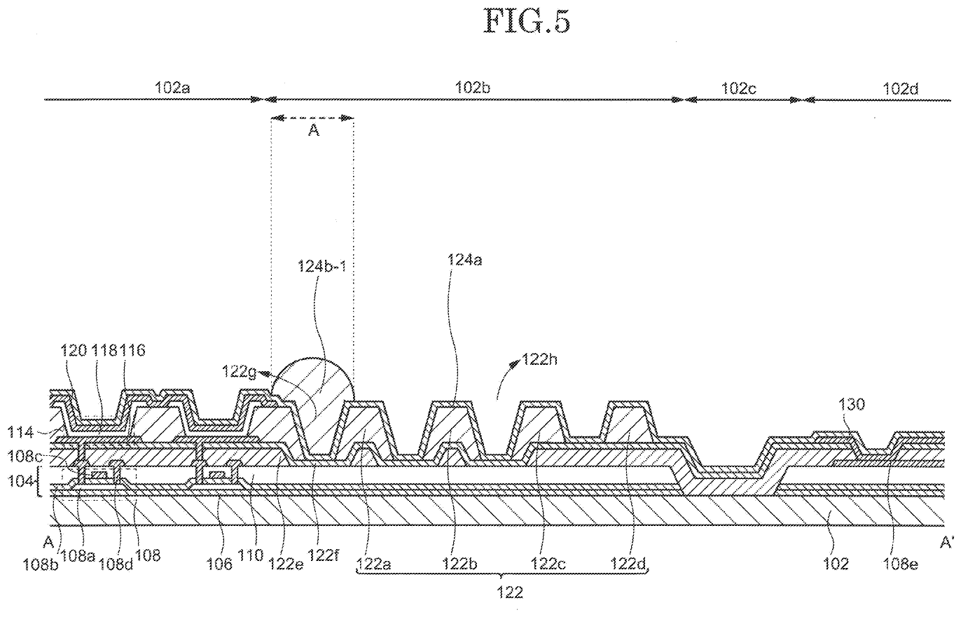

Next, a method of forming the sealing layer 124 will be described with reference to FIGS. 5 to 7. Here, the sealing layer 124 includes the first inorganic insulating layer 124a, the organic insulating layer 124b, and the second inorganic insulating layer 124c. The organic insulating layer 124b has the first part of the organic insulation layer 124b-1 and the second part of the organic insulation layer 124b-2. With reference to FIG. 5, a process for forming the first inorganic insulating layer 124a and the first part of the organic insulation layer 124b-1 on one surface of the substrate 102 will be described. The first inorganic insulating layer 124a is arranged over the surfaces of the substrate 102. The organic insulating layer 124b is arranged on the first inorganic insulating layer 124a, covers the plurality of pixel 112 and is arranged inside the first barrier 122a. The second inorganic insulating layer 124c is arranged on the organic insulating layer 124b and over the surfaces.

First, the first inorganic insulating layer 124a is formed over one surface of the substrate 102. The first inorganic insulating layer 124a may include an inorganic material such as, for example, silicon nitride, silicon oxide, silicon nitride oxide, or silicon oxynitride, and can be formed by the method similar to that of the underlayer 106.

Next, the first part of the organic insulation layer 124b-1 (first organic insulating layer) is formed. The first part of the organic insulation layer 124b-1 is formed in a first region A of the peripheral region 102b defined as a region inside the first inorganic insulating layer 124a. The first part of the organic insulation layer 124b-1 is formed by coating the inside of the first barrier 122a so as to surround the display region 102a using the wet film formation method such as an inkjet method. The first part of the organic insulation layer 124b-1 selectively applied to the first region A is blocked by the first barrier 122a.

Therefore, in this embodiment, the outer end of the first part of the organic insulation layer 124b-1 is formed on the first barrier 122a. However, it is not limited this, the first part of the organic insulation layer 124b-1 may have an outer end formed in the groove part 122g between the display region 102a and the first barrier 122a. The second barrier 122b is a spare wall when the organic insulating layer 124b has spread out to the outside of the first barrier 122a. Therefore, if the first part of the organic insulation layer 124b-1 has spread out to the outside of the first barrier 122a, the outer end may reach the groove part between the first barrier 122a and the second barrier 122b.

The first part of the organic insulation layer 124b-1 is formed so that the uppermost part of the first part of the organic insulation layer 124b-1 is higher than the top surface of the first inorganic insulating layer 124a on the first barrier 122a. That is, the uppermost part of the first part of the organic insulation layer 124b-1 of the organic insulating layer 124b is formed to have a larger distance than the upper surface of the first inorganic insulating layer 124a on the first barrier 122a from the substrate 102. By forming in this manner, the first part of the organic insulation layer 124b-1 can function as a larger barrier for blocking the later described second part of the organic insulation layer 124b-2 from spreading outside the first part of the organic insulation layer 124b-1.

The first part of the organic insulation layer 124b-1 is formed by curing photocuring resin materials. As the photocuring resin material, an organic resin material including acrylic resin, polysiloxane, polyimide, polyester, epoxy resin, silicone resin, and the like can be used. The viscosity of the photocuring resin material is preferably in the range of 10 cP or more and 30 cP or less. By the viscosity of the photocuring resin material is 10 cP or more, the flow of the photocuring resin material can be suppress, the first part of the organic insulation layer 124b-1 can be efficiently and selectively formed. By viscosity of the photocuring resin material is 30 cP or less, operability can be improved, and the groove part 122g between the display region 102a and the first barrier 122a can be efficiently filled.

The first part of the organic insulation layer 124b-1 is temporarily cured by irradiating the photocuring resin material. Wavelength region of the irradiation light is preferably ultraviolet and/or visible light region, more preferably ultraviolet. Wavelength region of the irradiation light can be appropriately selected by such light curing initiator contained in the photocuring resin material. The exposure amount of the irradiation light for temporarily curing the light curing resin material is preferably appropriately adjusted by the light curing initiator and the curable resin material included in the light curing resin material. The exposure amount when forming the first part of the organic insulation layer 124b-1 is smaller than the exposure amount when forming the second part of the organic insulation layer 124b-2 to be described later. Here, the exposure amount of the irradiation light depends on the irradiation intensity and the irradiation time. The first part of the organic insulation layer 124b-1 can be temporarily cured, so that the first part of the organic insulation layer 124b-1 can be obtained with enough strength as a barrier for blocking the second part of the organic insulation layer 124b-2 from spreading outside the first part of the organic insulation layer 124b-1, when forming the second part of the organic insulation layer 124b-2 to be described later. On the other hand, when the first part of the organic insulation layer 124b-1 is completely cured, the liquid repellency of the surface of the first part of the organic insulation layer 124b-1 becomes too high, and the photocuring resin material of the second part of the organic insulation layer 124b-2 is repelled. Therefore, by not completely curing the first part of the organic insulation layer 124b-1, the wettability of the surface of the first part of the organic insulation layer 124b-1 can be controlled, and the second part of the organic insulation layer 124b-2 can be efficiently apply.

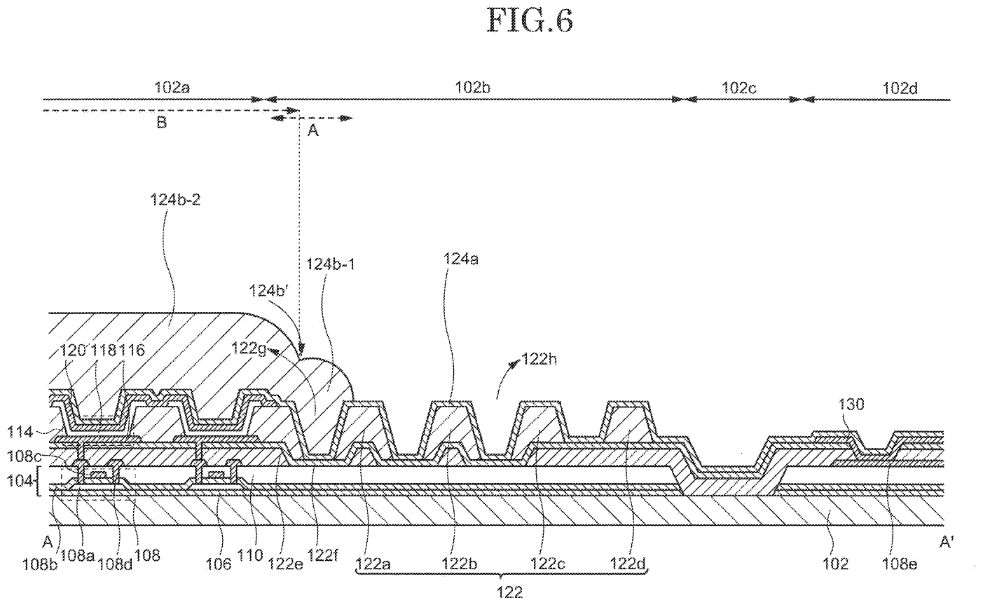

Next, a method for forming the second part of the organic insulation layer 124b-2 (the second organic insulating layer) will be described with reference to FIG. 6. The second part of the organic insulation layer 124b-2 is formed in a second region B including the display region 102a and the peripheral region 102b surrounded by the first region A. The second part of the organic insulation layer 124b-2 is formed by applying to the inside of the first part of the organic insulation layer 124b-1 so as to cover the display region 102a using the wet film formation method such as an inkjet method. The second part of the organic insulation layer 124b-2 selectively applied to the second region B is blocked by the first part of the organic insulation layer 124b-1. Therefore, in this embodiment, the outer end of the second part of the organic insulation layer 124b-2 is formed on the first part of the organic insulation layer 124b-1. That is, the second region B for arranging the second part of the organic insulation layer 124b-2 is partially overlaps with the first region A for arranging the first part of the organic insulation layer 124b-1. However, it is not limited to this, the second part of the organic insulation layer 124b-2 may be arranged so as to contact with the first part of the organic insulation layer 124b-1.

The second part of the organic insulation layer 124b-2 is formed so that the top of the second part of the organic insulation layer 124b-2 is higher than the top of the first part of the organic insulation layer 124b-1. That is, the organic insulating layer 124b is formed so that the distance from the substrate 102 is larger at the uppermost part of the second part of the organic insulation layer 124b-2 than the uppermost part of the first part of the organic insulation layer 124b-1. By forming in this manner, the second part of the organic insulation layer 124b-2 can be formed sufficiently thick in the display region 102a, and the unevenness due to the concavity and convexity or the foreign matter contamination and the like into the display region 102 can be suppressed.

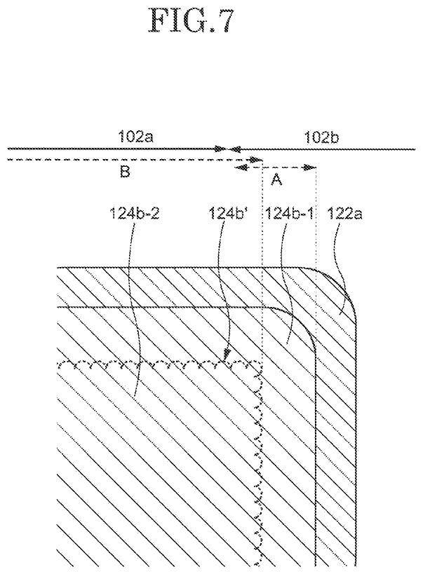

The concave 124b′ is formed at the boundary between the first part of the organic insulation layer 124b-1 and the second part of the organic insulation layer 124b-2. As shown in FIG. 7, the concave 124b′ which is an end of the second part of the organic insulation layer 124b-2, has the plurality of concave-convex shape in the outer direction of the display region 102a in the peripheral region 102b, when viewed from the top. On the other hand, the end of the first part of the organic insulation layer 124b-1 may have less concave-convex structures. Since the end portion of the second part of the organic insulation layer 124b-2 has such configuration, the adhesion between the organic insulating layer 124b and the second inorganic insulating layer 124c which is the upper layer of the organic insulating layer 124b can be improved.

The second part of the organic insulation layer 124b-2 is formed by curing photocuring resin materials. As the photocuring resin material, the same photocuring resin material as the first part of the organic insulation layer 124b-1 can be used. The viscosity of the photocuring resin material is preferably in the range of 10 cP or more and 30 cP or less. Since the viscosity of the photocuring resin material is 10 cP or more, the flow of the photocuring resin material can be suppressed, and the second part of the organic insulation layer 124b-2 can be formed inside the first part of the organic insulation layer 124b-sufficiently thick. By viscosity of the photocuring resin material is 30 cP or less, the operability can be improved, and the concavity and convexity of the plurality of pixel 112 of the display region 102a can be filled efficiently.

The second part of the organic insulation layer 124b-2 is cured by photo-irradiating the photocuring resin material. At this time, the temporarily cured first part of the organic insulation layer 124b-1 is also cured. The exposure amount when forming the second part of the organic insulation layer 124b-2 is larger than the exposure amount when forming the first part of the organic insulation layer 124b-1. Wavelength region and the exposure amount of the irradiation light can be appropriately selected by light curing initiator included in the light curing resin material.

Next, a method for forming the second inorganic insulating layer 124c will be described with reference to FIG. 7. The second inorganic insulating layer 124c has structures similar to that of the first inorganic insulating layer 124a and can be formed in a similar manner. The second inorganic insulating layer 124c can be formed so as to cover not only the organic insulating layer 124b but also the connecting electrodes. Thus, the organic insulating layer 124b can be sealed with the first inorganic insulating layer 124a and the second inorganic insulating layer 124c.

By the steps heretofore, the sealing layer 124 has a three-layer structure of the first inorganic insulating layer 124a, the organic insulating layer 124b and the second inorganic insulating layer 124c at the inside region of the first barrier 122a and a two-layer structure of the first inorganic insulating layer 124a and the second inorganic insulating layer 124c at the outside region of the first barrier 122a.

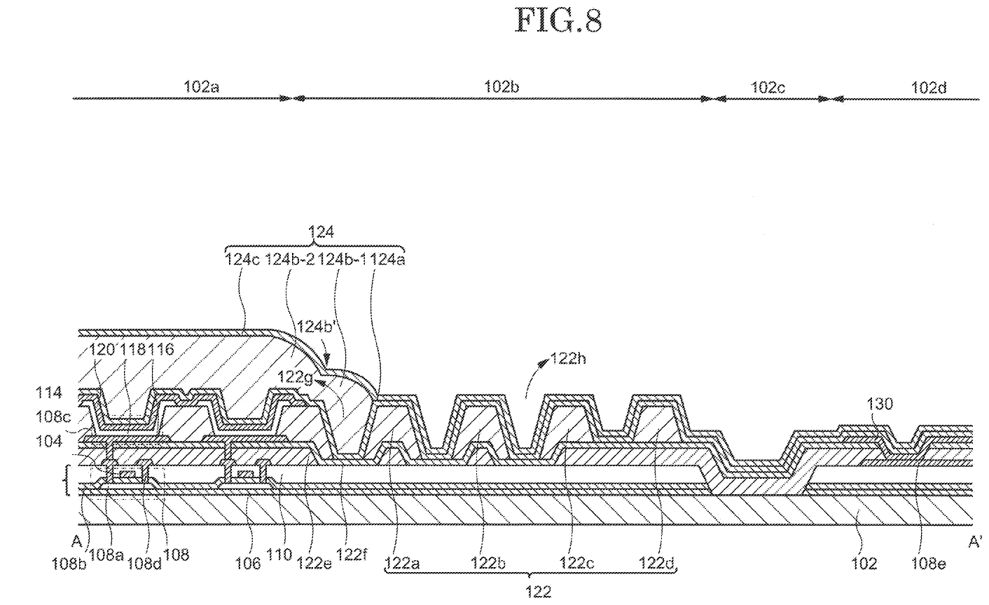

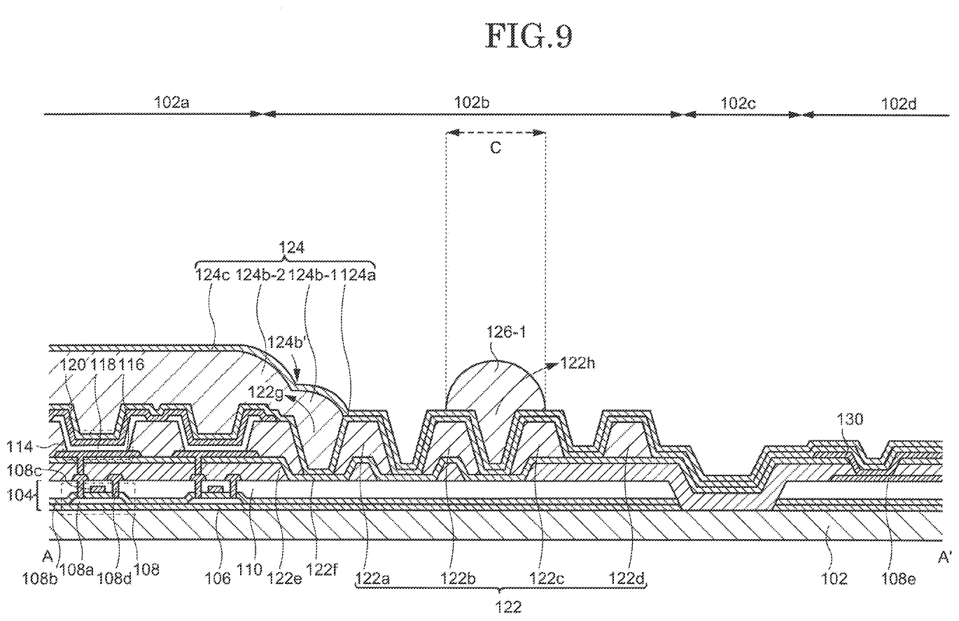

A method for forming the first protective layer 126 will be described with reference to FIGS. 8 and 9. The first protective layer 126 has the first part of the first protective layer 126-1 and the second part of the first protective layer 126-2. With reference to FIG. 8, a method for forming the first part of the first protective layer 126-1 (third organic insulating layer) on one surface of the substrate 102 will be described. The first part of the first protective layer 126-1 is formed in a third region C of the peripheral region 102b defined as an inner region of the first inorganic insulating layer 124a. The first part of the first protective layer 126-1 is formed by coating the inside of the third barrier 122c using the wet film formation method such as an inkjet method so as to surround the display region 102a. The first part of the first protective layer 126-1 selectively applied to the third region C is blocked by the third barrier 122c. Therefore, in this embodiment, the outer end of the first part of the first protective layer 126-1 is formed on the third barrier 122c. However, it is not limited to this, the outer end part of the first part of the first protective layer 126-1 may be formed in the groove part 122h between the second barrier 122b and the first barrier 122a. The fourth barrier 122d is a spare wall when the first protective layer 126 has spread out to the outside of the third barrier 122c. Therefore, when the first part of the first protective layer 126-1 has flowed out to the outside of the third barrier 122c, the outer end may reach the groove part between the third barrier 122c and the fourth barrier 122d.

The first part of the first protective layer 126-1 is formed such that the uppermost part of the first part of the first protective layer 126-1 is higher than the top surface of the second inorganic insulating layer 124c on the third barrier 122c. That is, the uppermost part of the first part of the first protective layer 126-1 is formed that the distance from the substrate is larger than the upper surface of the second inorganic insulating layer 124c on the third barrier 122c. By forming in this manner, the first part of the first protective layer 126-1 can function as a larger barrier for blocking the second part of the first protective layer 126-2 which will be described later from spreading outside the first part of the first protective layer 126-1.

The first part of the first protective layer 126-1 is formed by curing photocuring resin materials. As the photocuring resin material, the photocuring resin material of the same condition as the first part of the organic insulation layer 124b-1 can be used.

The first part of the first protective layer 126-1 is temporally cured by photo-irradiating the photocuring resin material. Wavelength region of the irradiation light is preferably ultraviolet and/or visible light region, more preferably ultraviolet. Wavelength region of the irradiation light can be appropriately selected by such light curing initiator contained in the photocuring resin material. The exposure amount of the irradiation light for temporarily curing the light curing resin material is preferably appropriately adjusted by the light curing initiator and the curable resin material included in the light curing resin material. The exposure amount when forming the first part of the first protective layer 126-1 is smaller than the exposure amount when forming the second part of the first protective layer 126-2 to be described later. The first part of the first protective layer 126-1 can be temporarily cured to provide enough strength as a barrier so that the second part of the first protective layer 126-2 does not spread outside the first part of the first protective layer 126-1 when forming the second part of the first protective layer 126-2 to be described later. On the other hand, when the first part of the first protective layer 126-1 is completely cured, the liquid repellency of the surface of the first part of the first protective layer 126-1 becomes too high, and the photocuring resin material of the second part of the first protective layer 126-2 is repelled. Therefore, by not completely curing the first part of the first protective layer 126-1, the wettability of the surface of the first part of the first protective layer 126-1 can be controlled, and the second part of the first protective layer 126-2 can be efficiently apply.

Next, a method for forming the second part of the first protective layer 126-2 (the fourth organic insulating layer) will be described with reference to FIG. 9. The second part of the first protective layer 126-2 is formed in a fourth region D including the display region 102a and the peripheral region 102b surrounded by the third region C. The second part of the first protective layer 126-2 is formed by applying to the inside of first part of the first protective layer 126-1 so as to cover the display region 102a using the wet film formation method such as an inkjet method. The second part of the first protective layer 126-2 selectively applied to the fourth region D is blocked by the first part of the first protective layer 126-1. Therefore, in this embodiment, the outer end of the second part of the first protective layer 126-2 is formed on the first part of the first protective layer 126-1. That is, the fourth region D where the second part of the first protective layer 126-2 is arranged partially overlaps with the third region C where the first part of the first protective layer 126-1 is arranged. However, it is not limited to this, the second part of the first protective layer 126-2 may be arranged so as to contact with the first part of the first protective layer 126-1.

The second part of the first protective layer 126-2 is formed so that the top of second part of the first protective layer 126-2 is higher than the top of first part of the first protective layer 126-1. That is, the first protective layer 126 is formed so that the distance from the substrate 102 is larger at the top of the second part of the first protective layer 126-2 than the top of the first part of the first protective layer 126-1. By forming in this manner, the second part of the first protective layer 126-2 can be formed sufficiently thick in the display region 102a, the concavity and convexity in the barrier layer 122 can be planarized.

The concave 126b′ is formed at the boundary between the first part of the first protective layer 126-1 and the second part of the first protective layer 126-2. The concave 126b′ which is an end of the second part of the first protective layer 126-2, has the plurality of concave-convex shape in the outer direction of the display region 102a in the peripheral region 102b, when viewed from the top. By having such configuration at the end of the second part of the first protective layer 126-2, the adhesion between the first protective layer 126 and the second protective layer 128 which is the upper layer of the first protective layer 126 can be improved.

The second part of the first protective layer 126-2 is formed by curing the photocuring resin materials. As the photocuring resin material, the same photocuring resin material as the first part of the first protective layer 126-1 can be used. The viscosity of the photocuring resin material is preferably in the range of 10 cP or more and 30 cP or less. Since the viscosity of the photocuring resin material is 10 cP or more, the flow of the photocuring resin material can be suppressed, and the second part of the first protective layer 126-2 can be formed sufficiently thick inside the first part of the first protective layer 126-1. By viscosity of the photocuring resin material is 30 cP or less, the operability can be improved, and the concavity and convexity in the barrier layer 122 can be filled efficiently.

The second part of the first protective layer 126-2 is cured by photo-irradiating the photocuring resin material. At this time, the temporarily cured first part of the first protective layer 126-1 is also cured. The exposure amount when forming the second part of the first protective layer 126-2 is larger than the exposure amount when forming the first part of the first protective layer 126-1. Wavelength region and the exposure amount of the irradiation light can be appropriately selected by light curing initiator included in the light curing resin material.

In this manner, the first protective layer 126, as shown in FIG. 9, covers the region where the first inorganic insulating layer 124a and the second inorganic insulating layer 124c are in contact with each other, and it is preferable to form so as not to overlap with the connection terminal 130.

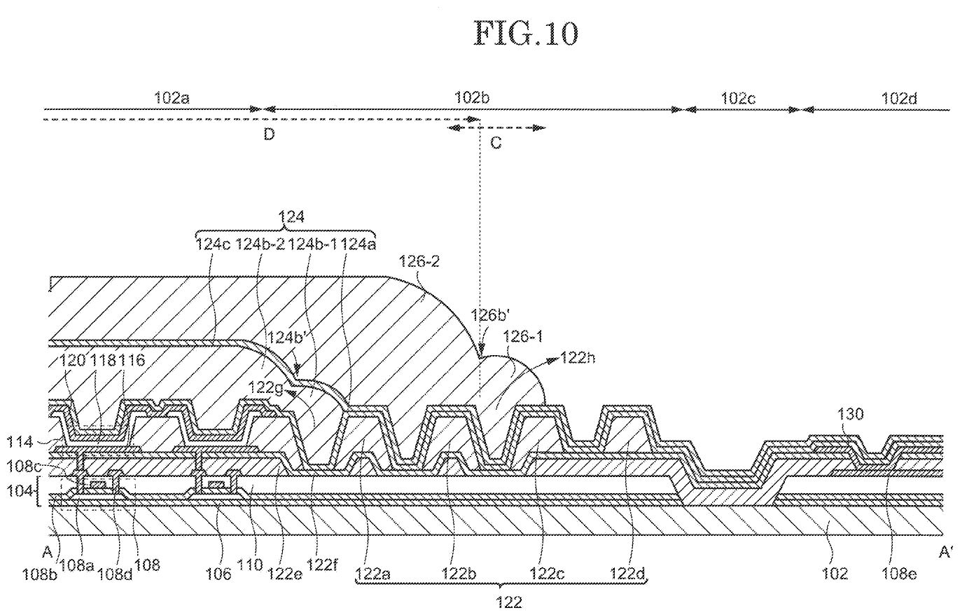

Next, with reference to FIG. 10, a method for exposing the plurality of connection terminals 130 which is covered by the sealing layer 124 by the previous steps. Here, the sealing layer 124 is etched to expose the plurality of connection terminals 130 using the first protective layer 126 as a mask. Here, the region of the sealing layer 124 exposed from the first protective layer 126 is a region having a two-layer structure of the first inorganic insulating layer 124a and the second inorganic insulating layer 124c.

The first protective layer 126 is thickened in the groove part near the end as described above. Therefore, in the step of etching the sealing layer 124, it is possible to prevent the recession of the end portion of the first protective layer 126. If the end of the first protective layer 126 is too receded, the etching of the sealing layer 124 is performed to the region where the three layers of the first inorganic insulating layer 124a, the organic insulating layer 124b, and the second inorganic insulating layer 124c are stacked. Therefore, there is a concern that the organic insulating layer 124b is exposed. When the organic insulating layer 124b is exposed, moisture enters therefrom, and then passes through the first inorganic insulating layer 124a, so that the light emitting layer 118 is deteriorated. As a result, the yield and reliability of the display device 100 decrease. Since the first inorganic insulating layer 124a is provided on the barrier layer 122 having concavity and convexity, cracks or the like is likely to occur, which can be an intrusion path of moisture.

Therefore, when the third barrier 122c is arranged and the first protective layer 126 having an end portion is formed on the third barrier 122c, the film thickness in the vicinity of the end portion of the first protective layer 126 can be increased by the groove part 122h between the second barrier 122b and the third barrier 122c. Thus, it is possible to prevent the recession of the end of the first protective layer 126 during etching of the sealing layer 124. This prevents the sealing layers 124 to be etched to unintentional regions and prevents the organic insulating layer 124b from being exposed. Then, the end of the first inorganic insulating layer 124a, the second inorganic insulating layer 124c and the first protective layer 126 can be formed on the third barrier 122c. Thus, the width of the peripheral region 102b can be reduced.

The second protective layer 128, the polarizer 132 and the cover film 134 are then formed. The second protective layer 128 can include polymeric materials such as polyesters, epoxy resins, acrylic resins, and can be formed by applying a printing method, laminating method, or the like. The cover film 134 can also include a polymeric material similar to the second protective layer 128, and in addition to the polymeric material described above, polymeric materials such as polyolefins, polyimides can also be applied. The display device 100 shown in FIG. 2 can be formed by connecting the connector using an anisotropic conductive film 136 or the like in the opening.

According to the method for manufacturing the display device 100 according to the present embodiment, it is possible to prevent deterioration of the sealing layer 124 in the manufacturing process. Thus, the display device 100 with improved production yield and reliability can be provided.

### Second Embodiment

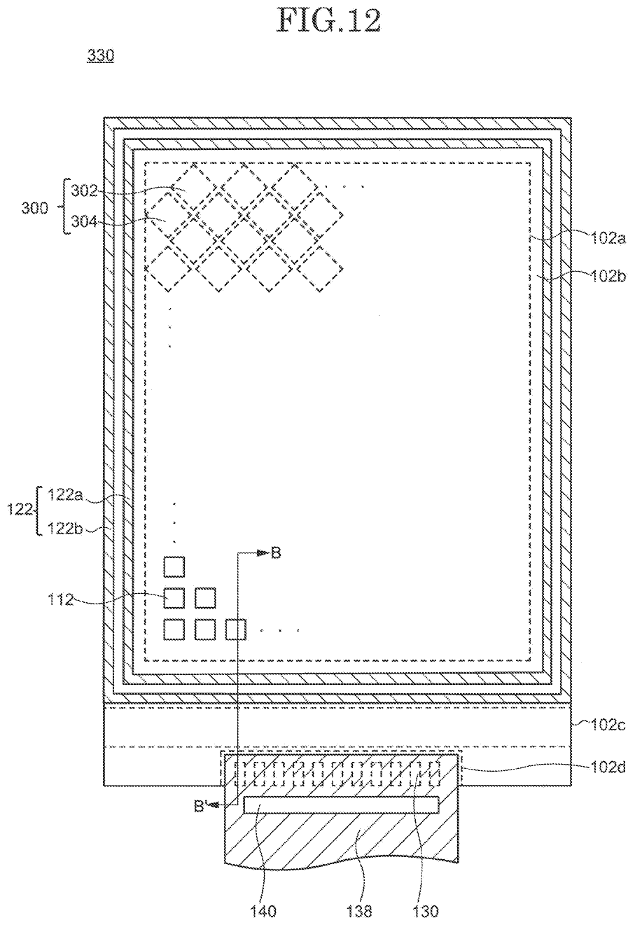

FIG. 12 is a top view showing the configuration of a display device 330 according to the present embodiment. The display device 330 according to the present embodiment is same as the first embodiment except for the differences that a touch sensor 300 is provided on the display region 102a so as to overlap with the light emitting element 114, and the description of repeating will be omitted.

As shown in FIG. 12, a plurality of first touch electrodes 302 and the second touch electrodes 304 are arranged in the display region 102a. The plurality of first touch electrodes 302 is arranged in stripes in the column direction. The plurality of second touch electrodes 304 is arranged in stripes in a row direction and intersects . One of the first touch electrode 302 and the second touch electrode 304 is referred it as a transmitting electrode (Tx), the other is referred to as a receiving electrode (Rx). Each of the first touch electrodes 302 and the second touch electrodes 304 comprise a plurality of square regions (diamond electrodes) having a substantially square shape. In the first touch electrodes 302 or the second touch electrodes 304, the adjacent diamond electrodes are electrically connected by the bridge electrodes. The first touch electrodes 302 and the second touch electrodes 304 are electrically independent of each other through an insulating film (capacitive insulating film 306), not shown in FIG. 12, and a capacitance is formed between them. When a finger or the like of a person touches the display region 102a through the first touch electrodes 302 and the second touch electrodes 304 (hereinafter, this operation is also referred to as touch), the capacitance changes, and the position of the touch is determined by reading this change. Thus, the first touch electrodes 302 and the second touch electrodes 304 form the touch sensor 300 of the so-called projection type capacitance method.

Each diamond electrode may comprise a conductive oxide that transmits visible light, such as ITO or IZO, or may be a mesh-like metal film. In the latter case, it is preferable to configure the diamond electrodes so that the opening of the mesh overlaps the pixel 112.

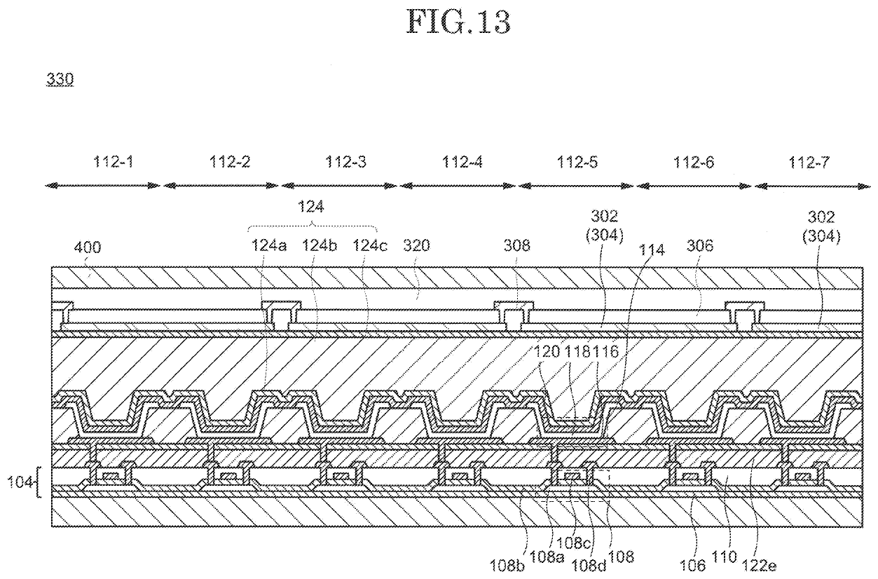

FIG. 13 is a cross-sectional view showing the configuration of the display device 330 according to the present embodiment, and it shows the configuration of the cross-section of the seven adjacent pixels 112 in the display region 102a (112-1, 112-2 . . . 112-7). The touch sensor 300 is provided on the sealing layer 124. Specifically, the first touch electrodes 302 or the second touch electrodes 304 is arranged on the second inorganic insulating layer 124c. However, it is not limited to this, an insulating layer may be arranged between the second inorganic insulating layer 124c and the first touch electrodes 302 or the second touch electrodes 304. The capacitive insulating film 306 is provided on the first touch electrodes 302 and the second touch electrodes 304, and a bridge electrode 308 is formed so as to overlap the opening arranged in the capacitive insulating film 306. The bridge electrode 308 electrically connects the adjacent diamond electrodes. The first touch electrodes 302, the second touch electrodes 304, and the capacitive insulating film 306 are the basic structures of the touch sensor 300. Although not shown, the second touch electrodes 304 may be arranged on the first touch electrodes 302 so as to sandwich the capacitive insulating film 306. In this case, the first touch electrodes 302 and the second touch electrodes 304 are in different layers from each other.

A protective insulating film 320 is provided on the touch sensor 300 on which a polarizing plate 400 can be arranged directly thereon or through an insulating film, not shown. Further, it may be further arranged a protective insulating film or an opposing substrate on the polarizing plate 400.

The peripheral region 102b may be arranged with the driving circuit for controlling the light emission of the plurality of pixel 112. In FIG. 12, the barrier layer 122 is shown in the peripheral region 102b. The barrier layer 122 has the first barrier 122a and the second barrier 122b at the peripheral region 102b. The first barrier 122a is spaced from the display region 102a, and has a ring shape surrounding the display region 102a. The second barrier 122b is spaced from the first barrier 122a, and has a ring shape surrounding the first barrier 122a.

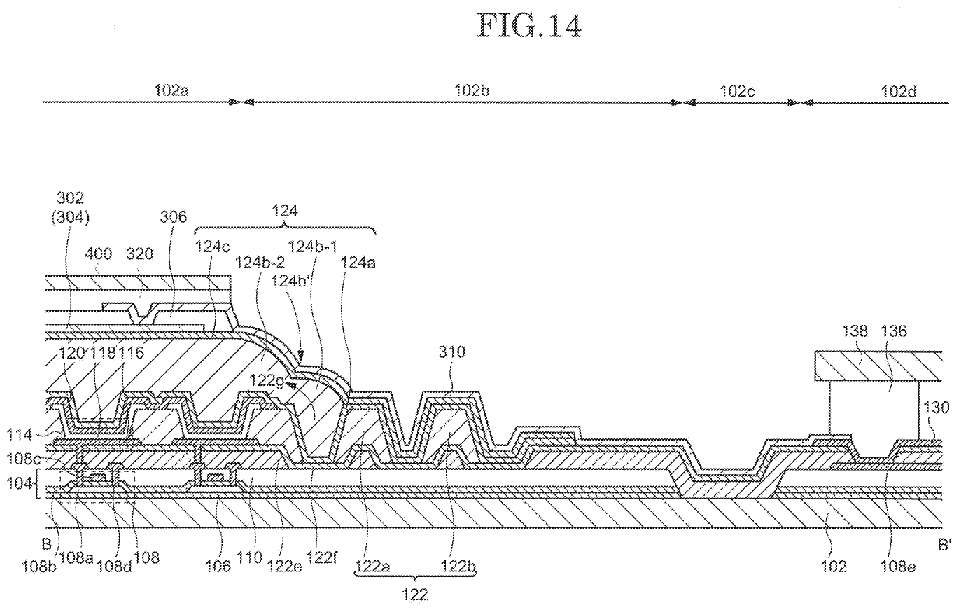

FIG. 14 is a cross-sectional view showing the configuration of the display device 330 according to the present embodiment, and shows the configuration of a cross section along the B-B′ shown in FIG. 12. The display device 330 includes the substrate 102, the circuit layer 104, the plurality of pixel 112, the barrier layer 122, the sealing layer 124, the touch sensor 300, a lead wiring 310, and the protective insulating film 320. The sealing layer 124 is configured to include the first inorganic insulating layer 124a, the organic insulating layer 124b, and the second inorganic insulating layer 124c.

The barrier layer 122 is provided on the one surface of the substrate 102. The barrier layer 122 in this embodiment has the first barrier 122a, the second barrier 122b, the planarized insulating layer 122e and the inorganic insulating layer 122f.

The first barrier 122a is spaced from the display region 102a in a plan view, and has a ring shape surrounding the display region 102a. Thus, the ring shape of the groove part 122g is formed between the display region 102a and the first barrier 122a. The organic insulating layer 124b is selectively applied to the display region 102a in two steps using, for example, an ink jet method. At this time, the first barrier 122a has a function of blocking the organic insulating layer 124b so that the organic insulating layer 124b does not spread to the outside of the first barrier 122a.

The second barrier 122b is spaced from the first barrier 122a in a plan view, and has a ring shape surrounding the first barrier 122a. The second barrier 122b is a spare wall when the organic insulating layer 124b has flowed out to the outside of the first barrier 122a. Therefore, the second barrier 122b is preferably arranged in the same configuration as the first barrier 122a.

The sealing layer 124 is provided on the upper layer of the plurality of pixel 112 and the barrier layer 122. The sealing layer 124 has the first inorganic insulating layer 124a, the organic insulating layer 124b and the second inorganic insulating layer 124c.

The first inorganic insulating layer 124a covers the concave-convex surfaces caused by the plurality of pixel 112 and the barrier layer 122. The outer end of the first inorganic insulating layer 124a is arranged at the outside of the second barrier 122b. That is, the first inorganic insulating layer 124a covers the bottom surface and the side walls of the groove part 122g between the plurality of pixel 112 and the first barrier 122a. Further, the first inorganic insulating layer 124a covers the bottom and side walls of the groove part between the first barrier 122a and the second barrier 122b.

The first inorganic insulating layer 124a has at least the following two roles. One is that the first inorganic insulating layer 124a is arranged so that the organic insulating layer 124b, which is arranged on the upper layer of the first inorganic insulating layer 124a and through which moisture easily permeates, does not contact the light emitting element 114. Thus, it is possible to prevent the moisture contained in the organic insulating layer 124b or the moisture entering the organic insulating layer 124b from the outside of the display device 100 from reaching the light emitting layer 118 and deteriorating the light emitting layer 118. The other is that the first inorganic insulating layer 124a is provided in order to prevent the first barrier 122a and the second barrier 122b from causing an entry path of moisture through organic materials. Thus, it is possible to prevent the moisture entering from the outside of the display device 330 from reaching the inside of the display region 102a and deteriorating the light emitting layer 118.

The organic insulating layer 124b has the first part of the organic insulation layer 124b-1 and the second part of the organic insulation layer 124b-2. The first part of the organic insulation layer 124b-1 and the second part of the organic insulation layer 124b-2 of the organic insulating layer 124b is arranged on the upper layer of the first inorganic insulating layer 124a. The first part of the organic insulation layer 124b-1 is a ring shape surrounding the display region 102a. The first part of the organic insulation layer 124b-1 is arranged in the first region of the peripheral region 102b defined as a region inside the first inorganic insulating layer 124a. The outer end of the first part of the organic insulation layer 124b-1 is arranged on the first barrier 122a. However, it is not limited to this, the outer end of the first part of the organic insulation layer 124b-1 may be arranged between the display region 102a and the first barrier 122a or between the first barrier 122a and the second barrier 122b. The first part of the organic insulation layer 124b-1, has a rounded convex shape with no corners from the outer end toward the display region 102a when viewed in cross-section. However, it is not limited to this, the surface shape of the first part of the organic insulation layer 124b-1 may have less concave-convex structure. The first part of the organic insulation layer 124b-1 of the organic insulating layer 124b can be blocked to prevent the second part of the organic insulation layer 124b-2 of the organic insulating layer 124b from spreading outward thereof.

The second part of the organic insulation layer 124b-2 is arranged to cover the display region 102a. The second part of the organic insulation layer 124b-2 is arranged in a second region including the display region 102a and the peripheral region 102b surrounded by a first region. The outer end of the second part of the organic insulation layer 124b-2 is in contact with the first part of the organic insulation layer 124b-1. The second part of the organic insulation layer 124b-2 has a rounded convex shape with no corners from the outer end toward the display region 102a, when viewed in cross-section. The second part of the organic insulation layer 124b-2 is substantially flat in the display region 102a. However, it is not limited to this, the second part of the organic insulation layer 124b-2 may have less concave-convex structures in the display region 102a. The organic insulating layer 124b is provided to planarize the concavity and convexity of the display region 102a due to the plurality of pixel 112. By forming the organic insulating layer 124b sufficiently thick in the display region 102a, the unevenness due to the concavity and convexity or the foreign matter contamination and the like into the display region 102a can be suppressed.

The boundary between the first part of the organic insulation layer 124b-1 and the second part of the organic insulation layer 124b-2 has the concave 124b′. The concave 124b′ which is the end of the second part of the organic insulation layer 124b-2 has a wavy shape at the periphery of the display region 102a, when viewed from the top. That is, the end of the second part of the organic insulation layer 124b-2 has the plurality of concave-convex shapes in the outer direction of the display region 102a in the peripheral region 102b. On the other hand, the end of the first part of the organic insulation layer 124b-1 may have less concave-convex structures. By the boundary between the first part of the organic insulation layer 124b-1 and the second part of the organic insulation layer 124b-2 has such a configuration, the adhesion between the organic insulating layer 124b and the second inorganic insulating layer 124c which is the upper layer of the organic insulating layer 124b can be improved.

The second inorganic insulating layer 124c is provided on the upper layer of the organic insulating layer 124b. The end of the second inorganic insulating layer 124c is also arranged at the outside of the second barrier 122b. In this embodiment, the second inorganic insulating layer 124c is arranged along the end of the first inorganic insulating layer 124a. Since the end portion of the first inorganic insulating layer 124a and the second inorganic insulating layer 124c are arranged outside of the second barrier 122b, the second barrier 122b can be completely coat by the first inorganic insulating layer 124a and the second inorganic insulating layer 124c. Thus, the effect of preventing moisture from entering to the display region 102a can be enhanced. The organic insulating layer 124b is sealed by the first inorganic insulating layer 124a and the second inorganic insulating layer 124c. With such a configuration, it is possible to block the penetration path of moisture from the outside to the inside of the display device 100 through the organic insulating layer 124b.

The touch sensor 300 and the lead wiring 310 are arranged on the upper layer of the sealing layer 124. The lead wiring 310 connects with the first touch electrodes 302 or the second touch electrodes 304 of the touch sensor 300 and extends to the terminal region 102d. The lead wiring 310 is electrically connected to the connection terminal 130, whereby signals for detecting the touch are supplied from external circuits (not shown) to the first touch electrodes 302 and the second touch electrodes 304.

According to the configuration of the display device 330, it is possible to prevent deterioration of the sealing layer 124. Thus, it is possible to provide the display device 330 with improved production yield and reliability.

The embodiments described above as embodiments of the present invention, can be implemented in the appropriate combination, as long as they are consistent with each other. Additionally, those skilled in the art may appropriately add, delete, or change the design of components, or may add, omit, or change the conditions of the steps, of the present invention. As long as it has the gist, it is included in the scope of the present invention.

While the present specification exemplified the case of a display device using a light emitting element as an embodiment, other applications include any flat panel display device, such as other self-emitting display devices, liquid crystal display devices, or electronic paper display devices having an electrophoretic element or the like can be applied. Further, the present invention can be applied from small and medium to large without any particular limitation.

Furthermore, even if other actions and effects different from the actions and effects brought about by the aspects of each embodiment described above are obvious from the description of the present specification or those which could be easily predicted by those skilled in the art, such actions and effects are to be interpreted as being provided by the present invention.

What is claimed is:

1. A method of manufacturing a display device, the method comprising:
forming a first inorganic insulation layer on a surface including a display region of a substrate;
forming a first organic insulation layer in a first region on the first inorganic insulation layer, the first region surrounding the display region and defined as an inner region of the first inorganic insulation layer;
forming a second organic insulation layer in contact with the first organic insulation layer in a second region on the first inorganic insulation layer, the second region covering the display region and surrounded by the first region; and
forming a second inorganic insulation layer in contact with the first inorganic insulation layer outside the first organic insulation layer, the second inorganic insulation layer covering the first organic insulation layer and the second organic insulation layer.

2. The method of manufacturing the display device according to claim 1, wherein;
forming the first organic insulation layer and the second organic insulation layer includes applying by an inkjet method and curing by light, respectively; and
an exposure amount for forming the first organic insulation layer is smaller than an exposure amount for forming the second organic insulation layer.

3. The method of manufacturing the display device according to claim 1, wherein;
the first region and the second region overlap.

4. The method of manufacturing the display device according to claim 1, further comprising;
forming a third organic insulation layer in a third region on the second inorganic insulation layer, the third region surrounding the first region and defined as an inner region of the second inorganic insulation layer; and
forming a fourth organic insulation layer in contact with the third organic insulation layer in a fourth region on the second inorganic insulation layer, the fourth region covering the display region and surrounded by the third region.

5. The method of manufacturing the display device according to claim 4, wherein;
forming the third organic insulation layer and the fourth organic insulation layer includes applying by an inkjet method and curing by light, respectively; and
an exposure amount of the third organic insulation layer is smaller than an exposure amount of the fourth organic insulation layer.

6. The method of manufacturing the display device according to claim 4, wherein;
the third region and the fourth region overlap.

7. The method of manufacturing the display device according to claim 4, further comprising;
forming a first barrier arranged at the end of the first region and surrounding the first region on a surface including the display region of the substrate.

8. The method of manufacturing the display device according to claim 7, wherein;
forming the first organic insulation layer includes applying inside of the first barrier.

9. The method of manufacturing the display device according to claim 7, further comprising;
forming a second barrier surrounding the first barrier on a surface including the display region of the substrate; and
forming a third barrier surrounding the second barrier at the end of the third region.

10. The method of manufacturing the display device according to claim 9, wherein;
forming the third organic insulation layer includes applying inside of the third barrier.

11. The method of manufacturing the display device according to claim 9, further comprising;
forming a fourth barrier surrounding the third barrier on a surface including the display region of the substrate; and
forming a plurality of connecting terminals outside the fourth barrier on a surface including the display region of the substrate.

12. The method of manufacturing the display device according to claim 4, wherein;
a distance from the substrate to the top of the second organic insulation layer is formed larger than a distance from the substrate to the top of the first organic insulation layer.

13. The method of manufacturing the display device according to claim 4, wherein;
a distance from the substrate to the top of the fourth organic insulation layer is formed larger than a distance from the substrate to the top of the third organic insulation layer.

14. The method of manufacturing the display device according to claim 1, wherein;
the first organic insulation layer and the second organic insulation layer are formed using the same photocuring resin material.

15. The method of manufacturing the display device according to claim 4, wherein;
the third organic insulation layer and the fourth organic insulation layer are formed using the same photocuring resin material.

16. A display device comprising:
a substrate having a display region;
a first inorganic insulation layer arranged on a surface including the display region;
an organic insulation layer including a first part arranged at a first region surrounding the display region and defined as an inner region of the first inorganic insulation layer, and a second part arranged at a second region covering the display region and surrounded by the first region; and
a second inorganic insulation layer covering the organic insulation layer and in contact with the first inorganic insulation layer outside of the organic insulation layer;
wherein the organic insulation layer has a concave part at a boundary between the first part and the second part.

17. The method of manufacturing the display device according to claim 16, wherein;
a contact angle of the second part is larger than a contact angle of the first part.

18. The method of manufacturing the display device according to claim 16, wherein;
the substrate includes a first barrier arranged at the end of the first region and surrounding the first region on a surface including the display region.

19. The method of manufacturing the display device according to claim 18, wherein;
the organic insulation layer is arranged inside the first barrier.

20. The method of manufacturing the display device according to claim 19, wherein;
the second part has a concave-convex structure at a boundary with the first part.
